(19) United States
(12) Patent Application Publication
(10) Pub. No.: US 2026/0190617 A1
(43) Pub. Date: Jul. 2, 2026

(54) DISPLAY DEVICE

(71) Applicant: LG Display Co., Ltd., Seoul (KR)

(72) Inventors: Soyeong JEONG, Paju-si (KR); KwanSoo KIM, Paju-si (KR); JongWoo PARK, Paju-si (KR); MinJee KIM, Paju-si (KR); SeokHyun KIM, Paju-si (KR); JiHyun ROH, Paju-si (KR)

(73) Assignee: LG Display Co., Ltd., Seoul (KR)

(21) Appl. No.: 19/435,372

(22) Filed: Dec. 29, 2025

(30) Foreign Application Priority Data
Dec. 30, 2024 (KR) 10-2024-0200341

(51) Int. Cl. H10K 50/84; H10K 50/822

(52) U.S. Cl. CPC H10K 50/841; H10K 50/822

(57) ABSTRACT

A display device can include a substrate having a display area in which an image is displayed where the display area includes a transmissive area in which light is transmitted and a normal area located outside of the transmissive area, an anode electrode located on the substrate, a bank located on the anode electrode having a bank hole for exposing a portion of the anode electrode, an intermediate layer disposed in the display area and contacting an upper surface of the portion of the anode electrode exposed through the bank hole, a cathode electrode disposed in the display area and including a cathode hole located to overlap with at least a portion of the transmissive area, a first adhesive reinforcing layer disposed in the cathode hole and including a first amphoteric material, and a metal patterning layer disposed on the first adhesive reinforcing layer and including a cathode patterning material.

### CROSS-REFERENCE TO RELATED APPLICATION

This application claims priority to Korean Patent Application No. 10-2024-0200341, filed on Dec. 30, 2024 in the Korean Intellectual Property Office, which is hereby expressly incorporated by reference for all purposes as if fully set forth herein.

### BACKGROUND

### Technical Field

The present disclosure relates to electronic devices, and more specifically, to display devices.

### Discussion of the Related Art

As display technology has been advanced, display devices have been developed to provide increased functions, such as an image capture function, a sensing function, and the like, as well as an image display function. To provide these functions, display devices have been equipped with optical electronic devices, such as a camera, a sensor for detecting an image, a sensor for detecting light, a light receiving device, and the like.

To effectively receive light passing through the front surface of a display device, it can be desirable for such an optical electronic device to be located in an area of the display device where incident light coming through the front surface can be increasingly received and detected. Taking account of this issue, typical display devices have employed a structure in which an optical electronic device is located in a front portion of the display devices to allow the optical electronic device to be effectively exposed to incident light. To install such an optical electronic device such as a camera, a sensor, and the like in a display device in this structure, a bezel of the display device can be increased, or a notch or a hole for accommodating the optical electronic device can be needed to be formed in a display area of a display panel.

According to this configuration, as an optical electronic device such as a camera, a sensor, and the like for receiving or detecting light being incident through the front surface and performing an intended function is included in a display device, the size of a bezel in the front of the display device can be increased, or a substantial limitation can be imposed on designing a front portion of the display device.

In an example where an optical electronic device is included in a display device, unexpected image quality degradation can occur depending on a structure where the optical electronic device is disposed in the display device, and in addition, the performance of the optical electronic device can also be degraded. For example, when the optical electronic device is a camera, the image quality obtained from the camera can be degraded.

### SUMMARY OF THE DISCLOSURE

To address these issues, one or more aspects of the present disclosure can provide a display device that includes a light transmissive structure capable of enabling at least one optical electronic device disposed under, or at a lower portion of, a display panel to normally receive light (e.g., visible light, infrared light, ultraviolet light, or the like) while not being exposed in the front of the display device.

One or more aspects of the present disclosure can provide a display device that includes a structure where at least one optical electronic device is disposed to be overlapped with a display area of a display panel while being located under the display area, and is capable of enabling a full-screen display to be implemented by using all of the display area as a display screen.

One or more aspects of the present disclosure can provide a display device that includes a structure where an interlayer adhesion is improved in a transmissive area of a display panel overlapping with an optical electronic device, and is capable of improving the reliability of the display panel.

One or more aspects of the present disclosure can provide a display device that includes a structure where the degradation of luminance and the reduction of lifetime can be reduced in an optical area of a display panel overlapping with an optical electronic device, and is capable of improving the reliability of light emitting elements.

One or more aspects of the present disclosure can provide a display device that includes a structure capable of improving the transmittance of an optical area of a display panel overlapping with an optical electronic device.

Aspects, examples, and embodiments provided in the present disclosure are not limited to the foregoing description, and additional aspects, examples, and embodiments provided in the present disclosure will become apparent to those skilled in the art from the following description.

According to one or more example embodiments of the present disclosure, a display device can include a substrate including a display area in which an image is displayed, the display area including a transmissive area in which light is transmitted and a normal area located outside of the transmissive area, an anode electrode located on the substrate, a bank located on the anode electrode and including a bank hole for exposing a portion of the anode electrode, an intermediate layer disposed in the display area and contacting an upper surface of the portion of the anode electrode exposed through the bank hole, a cathode electrode disposed in the display area, located on the intermediate layer, and including a cathode hole overlapping with at least a portion of the transmissive area, a first adhesion reinforcing layer disposed in the cathode hole and including a first amphoteric material, and a metal patterning layer disposed on the first adhesion reinforcing layer and including a cathode patterning material.

According to one or more example embodiments of the present disclosure, a display device can include a substrate including a display area in which an image is displayed, the display area including a transmissive area in which light is transmitted and a normal area located outside of the transmissive area, an anode electrode located on the substrate, a bank located on the anode electrode and including a bank hole for exposing a portion of the anode electrode, an intermediate layer disposed in the display area and contacting an upper surface of the portion of the anode electrode exposed through the bank hole, a cathode electrode disposed in the display area, located on the intermediate layer, and including a cathode hole overlapping with at least a portion of the transmissive area, a metal patterning layer disposed in the cathode hole and including a cathode patterning material, an adhesion reinforcing layer disposed on the metal patterning layer and including an amphoteric material, and a capping layer disposed in the display area, located on the cathode electrode, and covering the cathode hole.

According to one or more aspects of the present disclosure, a display device can include a light transmissive structure capable of enabling at least one optical electronic device disposed under, or at a lower portion of, a display panel to normally receive light (e.g., visible light, infrared light, ultraviolet light, or the like) while not being exposed in the front of the display device.

According to one or more aspects of the present disclosure, a display device can enable a full-screen display to be implemented by using all of a display area as a display screen by including a structure where at least one optical electronic device is disposed to be overlapped with the display area of a display panel while being located under the display area.

According to one or more aspects of the present disclosure, a display device can include a structure capable of improving the transmittance of an optical area of a display panel overlapping with an optical electronic device.

According to one or more aspects of the present disclosure, a display device can improve the reliability of the display panel by including a structure where an interlayer adhesion is improved in a transmissive area of a display panel overlapping with an optical electronic device.

According to one or more aspects of the present disclosure, a display device can include a structure where the degradation of luminance and the reduction of lifetime can be reduced in an optical area of a display panel overlapping with an optical electronic device, and thereby, is capable of being designed to have high efficiency and improved lifespan and be driven with low power.

Effects or advantages from aspects, examples, and embodiments described herein are not limited thereto, and additional effects or advantages will become apparent to those skilled in the art from the following description.

### BRIEF DESCRIPTION OF THE DRAWINGS

The accompanying drawings, which are included to provide a further understanding of the disclosure and are incorporated in and constitute a portion of the disclosure, illustrate aspects of the disclosure and together with the description serve to explain principles of the disclosure. It should therefore be understood that aspects, examples, and embodiments described herein are not limited to the illustrations of the accompanying drawings. In the drawings:

FIGS. 1 to 3 illustrate configurations of an example display device according to aspects of the present disclosure;

FIG. 4 illustrates an example system configuration of the display device according to aspects of the present disclosure;

FIG. 5 illustrates a configuration of an example display panel according to aspects of the present disclosure;

FIG. 6 illustrates an example configuration of a first type of optical area and a normal area outside of the first type of optical area in the display panel according to aspects of the present disclosure;

FIG. 7 is an example plan view illustrating a normal area, an optical bezel area, and an optical area in the display panel according to aspects of the present disclosure;

FIG. 8 is an example cross-sectional view of the optical bezel area and the optical area in the display panel according to aspects of the present disclosure;

FIG. 9 illustrates an example configuration of a second type of optical area and a normal area around an edge of the second type of optical area in the display panel according to aspects of the present disclosure;

FIG. 10 is an example plan view of the second type of optical area in the display panel according to aspects of the present disclosure;

FIG. 11 is an example cross-sectional view of the second type of optical area in the display panel according to aspects of the present disclosure;

FIG. 12 illustrates an example structure of an adhesion reinforcement material according to aspects of the present disclosure;

FIGS. 13 to 15 illustrate various example enlarged cross-sections of area A illustrated in FIG. 11 according to aspects of the present disclosure;

FIG. 16A is a photograph showing an image according to a comparative example not including an adhesion reinforcing layer; and

FIG. 16B is a photograph showing an image according to an example embodiment of the present disclosure including an adhesion reinforcing layer.

### DETAILED DESCRIPTION OF THE EMBODIMENTS

Reference will now be made in detail to example embodiments of the present disclosure, examples or aspects of which can be illustrated in the accompanying drawings. In the following description, the structures, implementations, methods, and operations described herein are not limited to the specific examples, aspects, and embodiments set forth herein and can be changed as is known in the art, unless otherwise specified. Like reference numerals designate like elements throughout, unless otherwise specified. Names of the respective elements used in the following explanations are selected only for convenience of writing the disclosure and can thus be different from those used in actual products. Advantages and features of the present disclosure, and implementation methods thereof will be clarified through following example embodiments described with reference to the accompanying drawings. The present disclosure may, however, be embodied in different forms and should not be construed as limited to the example embodiments set forth herein. Rather, these example embodiments are provided so that this disclosure can be sufficiently thorough and complete to assist those skilled in the art to fully understand the scope of the present disclosure. Further, the protected scope of the present disclosure is defined by claims and their equivalents. In the following description, where the detailed description of the relevant known function or configuration can unnecessarily obscure aspects of the present disclosure, a detailed description of such known function or configuration can be omitted. The shapes, sizes, ratios, angles, numbers, and the like, which are illustrated in the drawings to describe various example embodiments of the present disclosure, are merely given by way of example. Therefore, the present disclosure is not limited to the illustrations in the drawings. The terms such as “including”, “having”, “containing”, “constituting” and “comprising” used herein are generally intended to allow other components to be added unless the terms are used with the term “only.” As used herein, singular forms are intended to include plural forms unless the context clearly indicates otherwise.

Although the terms such as “first,” “second,” A, B, (a), (b), and the like can be used herein to describe various elements, these elements should not be interpreted to be limited by these terms as they are not used to define a particular order or precedence. These terms are used only to distinguish one element from another. For example, a first element could be termed a second element, and, similarly, a second element could be termed a first element, without departing from the scope of the present disclosure.

When it is mentioned that a first element “is connected or coupled to”, “overlaps with”, or the like a second element, it should be interpreted that, not only can the first element “be directly connected or coupled to”, “directly contact”, or “directly overlap with” the second element, but a third element can also be “interposed” between the first and second elements, or the first and second elements can “be connected or coupled to”, “overlap with”, or the like each other via a fourth element. Here, the second element can be included in at least one of two or more elements that “are connected or coupled to”, “overlap with”, or the like each other.

Where positional relationships are described, for example, where the positional relationship between two parts is described using terms such as “on,” “over,” “under,” “above,” “below,” “beside,” “next,” or the like, one or more other parts can be located between the two parts unless a more limiting term, such as “immediate(ly),” “direct(ly),” or “close(ly)” is used. For example, where an element or layer is disposed “on” another element or layer, a third element or layer can be interposed therebetween. Furthermore, the terms “left,” “right,” “top,” “bottom, “downward,” “upward,” “upper,” “lower,” and the like refer to an arbitrary frame of reference.

In addition, when any dimensions, relative sizes etc. are mentioned, it should be considered that numerical values for an elements or features, or corresponding information (e.g., level, range, and the like) include a tolerance or error range that can be caused by various factors (e.g., process factors, internal or external impact, noise, and the like) even when a relevant description is not specified. Further, the term “can” fully encompasses all the meanings of the term “may” and vice versa.

In the following description, various example aspects of the present disclosure are described in detail with reference to the accompanying drawings. With respect to reference numerals to elements of each of the drawings, the same elements can be illustrated in other drawings, and like reference numerals can refer to like elements unless stated otherwise. The same or similar elements can be denoted by the same reference numerals even though they are depicted in different drawings. In addition, for convenience of description, a scale, dimension, size, and thickness of each of the elements illustrated in the accompanying drawings can be different from an actual scale, dimension, size, and thickness, and thus, aspects of the present disclosure are not limited to a scale, dimension, size, and thickness illustrated in the drawings. Further, all the components of each display device/apparatus according to all embodiments of the present disclosure are operatively coupled and configured.

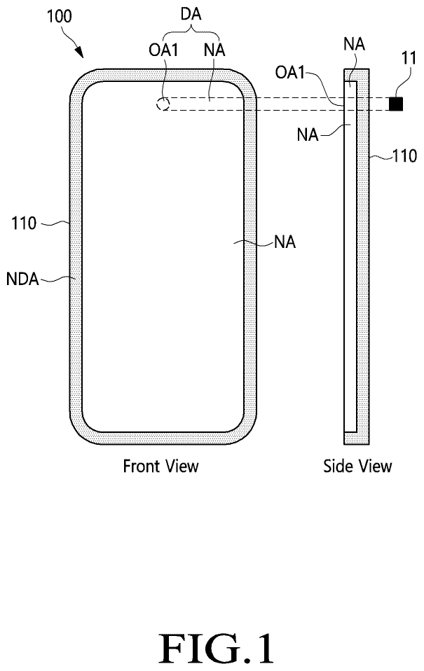

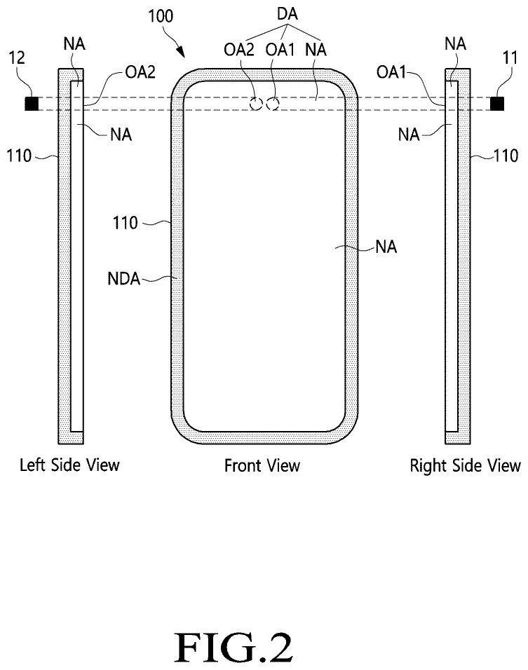

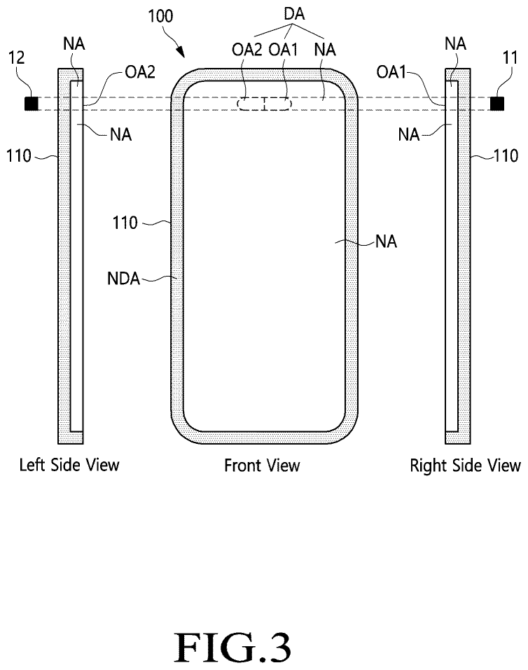

FIGS. 1 to 3 illustrate configurations of an example display device 100 according to aspects of the present disclosure.

Referring to FIGS. 1 to 3, in one or more example embodiments of the present disclosure, the display device 100 can include a display panel 110 for displaying an image, and one or more optical electronic devices (e.g., a first optical electronic device 11 and/or a second optical electronic device 12). Herein, an optical electronic device can be referred to as a light detector, a light receiver, or a light sensing device. An optical electronic device can include one or more of a camera, a camera lens, a sensor, a sensor for detecting images, and the like.

The display panel 110 can include a display area DA in which one or more images can be displayed and a non-display area NDA in which an image is not displayed.

A plurality of subpixels can be disposed in the display area DA, and several types of signal lines for driving the plurality of subpixels can be disposed therein.

The non-display area NDA can represent an area outside of the display area DA or an area around an outer edge of the display area DA. Several types of signal lines can be disposed in the non-display area NDA, and several types of driving circuits can be connected to, or located in the non-display area NDA. At least a portion of the non-display area NDA can be bent, and thereby, be invisible from the front surface of the display device 100 or be covered by a case or housing of the display device 100. The non-display area NDA can also be referred to as a non-active area, a bezel, or a bezel area.

In one or more aspects, the one or more optical electronic devices (11 and/or 12) can be prepared as separate devices from the display panel 110 and thereafter included in the display device 100. For example, the one or more optical electronic devices (11 and/or 12) can be located under, or at a lower portion of, the display panel 110 (an opposite side to the viewing surface thereof).

Light can enter the front surface (the viewing surface) of the display panel 110, pass through the display panel 110, reach one or more optical electronic devices (11 and/or 12) located under, or at the lower portion of, the display panel 110 (the opposite side of the viewing surface). Light passing through the display panel 110 can include, for example, visible light, infrared light, ultraviolet light, or the like.

The one or more optical electronic devices (11 and/or 12) can be devices capable of receiving or detecting light passing through the display panel 110 and perform a predefined function based on the received light. For example, the one or more optical electronic devices (11 and/or 12) can include one or more of the following: an image capture device such as a camera, an image sensor, and/or the like; and a sensor such as a proximity sensor, an illuminance sensor, and/or the like. For example, the sensor can be an infrared sensor capable of performing a predetermined operation using infrared light.

In one or more aspects, the display area DA of the display panel 110 can include one or more optical areas (OA1 and/or OA2) and a normal area NA. Herein, the term “normal area” NA can be an area that while being present in the display area DA, does not overlap with one or more optical electronic devices (11 and/or 12) and can also be referred to as a non-optical area. The one or more optical areas (OA1 and/or OA2) can be one or more areas respectively overlapping with the one or more optical electronic devices (11 and/or 12) in a plan view.

The normal area NA and the one or more optical areas (OA1 and/or OA2) included in the display area DA can be areas where an image can be displayed. It should be noted here that the normal area NA can be an area in which a light transmissive structure need not be implemented, and the one or more optical areas (OA1 and/or OA2) can be areas in which a light transmissive structure is needed to be implemented.

For example, the one or more optical areas (OA1 and/or OA2) can have a resolution, a subpixel arrangement structure, the number of subpixels per unit area, an electrode structure, a line structure, an electrode arrangement structure, a line arrangement structure, or/and the like different from that/those of the normal area NA.

In one or more aspects, the number of subpixels per unit area in the one or more optical areas (OA1 and/or OA2) can be less than the number of subpixels per unit area in the normal area NA. For example, the resolution of the one or more optical areas (OA1 and/or OA2) can be lower than that of the normal area NA. Here, the number of subpixels per unit area can have the same meaning as resolution, density of pixels, or integration degree of pixels. For example, the number of subpixels per unit area can be represented as pixels per inch (PPI), which represents the number of pixels in one inch.

The one or more optical areas (OA1 and/or OA2) can include a first optical area OA1 and a second optical area OA2. The first optical area OA1 can have various shapes, such as a circle, an ellipse, a quadrangle, a hexagon, an octagon or the like. The second optical area OA2 can have various shapes, such as a circle, an ellipse, a quadrangle, a hexagon, an octagon or the like. The first optical area OA1 and the second optical area OA2 can have the same or substantially or nearly the same shape, or different shapes.

Herein, the display device 100 having a structure in which the first optical electronic device 11 such as a camera, and the like is located under, or at a lower portion of, the display panel 100 without being exposed to the outside can be referred to as a display in which under-display camera (UDC) technology is implemented.

Herein, the display device 100 having a structure in which the second optical electronic device 12, for example, a sensor such as a proximity sensor, an illuminance sensor, an infrared sensor, or the like is located under, or at a lower portion of, the display panel 100 without being exposed to the outside can be referred to as a display to which under-display infrared (UDIR) technology is implemented.

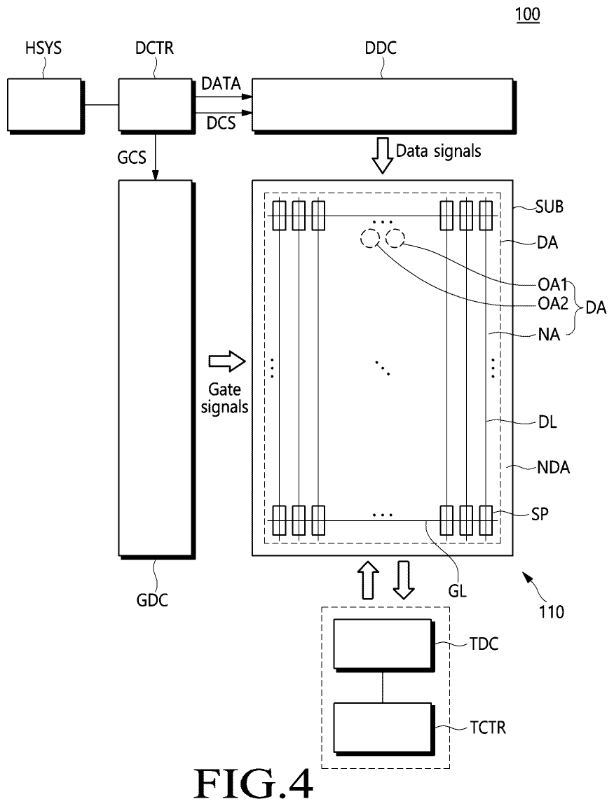

FIG. 4 illustrates an example system configuration of the display device 100 according to aspects of the present disclosure. In discussions that follow for the configuration of FIG. 4, discussions for features and configurations equal, substantially equal, or similar to the features and configurations described with reference to FIGS. 1 to 3 are omitted or briefly described for conciseness.

Referring to FIG. 4, in one or more example embodiments of the present disclosure, the display device 100 can include the display panel 110 and at least one display driving circuit as components for displaying one or more images.

The display driving circuit can be a circuit for driving the display panel 110, and include a data driving circuit DDC, a gate driving circuit GDC, a display controller DTCR, and other circuit components.

The display panel 110 can include a substrate SUB and a plurality of subpixels SP disposed on the substrate SUB. The display panel 110 can further include several types of signal lines for driving the plurality of subpixels SP.

In one or more aspects, the display device 100 can be a liquid crystal display device, or the like, or a self-emissive display device in which light is emitted from the display panel 110 itself. In an example where the display device 100 is the self-emissive display device, each of a plurality of subpixels SP included in the display panel 110 can include a light emitting element.

The structure of each of the plurality of subpixels SP can be differently configured or designed according to types of the display device 100. For example, in an example where the display device 100 is a self-emissive display device including self-emissive subpixels SP, each subpixel SP can include a self-emissive light emitting element, one or more transistors, and one or more capacitors.

In one or more aspects, several types of signal lines disposed in the display device 100 can include, for example, a plurality of data lines DL for delivering data signals (which can be referred to as data voltages or image signals), a plurality of gate lines GL for delivering gate signals (which can be referred to as scan signals), and the like.

The plurality of data lines DL and the plurality of gate lines GL can intersect each other. Each of the plurality of data lines DL can extend in a first direction. Each of the plurality of gate lines GL can extend in a second direction different from the first direction. For example, the first direction can be the column or vertical direction, and the second direction can be the row or horizontal direction. In another example, the first direction can be the row or horizontal direction, and the second direction can be the column or vertical direction.

The data driving circuit DDC can be a circuit for driving the plurality of data lines DL, and can supply data signals to the plurality of data lines DL. The gate driving circuit GDC can be a circuit for driving the plurality of gate lines GL, and can supply gate signals to the plurality of gate lines GL.

The display controller DCTR can be a device for controlling the data driving circuit DDC and the gate driving circuit GDC, and can control driving times for the plurality of data lines DL and driving times for the plurality of gate lines GL.

The display controller DCTR can supply a data driving control signal DCS to the data driving circuit DDC to control the data driving circuit DDC, and supply a gate driving control signal GCS to the gate driving circuit GDC to control the gate driving circuit GDC.

The display controller DCTR can receive input image data from a host system HSYS and supply image data DATA readable by the data driving circuit DDC based on the input image data to the data driving circuit DDC.

The data driving circuit DDC can receive digital image data DATA from the display controller DCTR, convert the received image data DATA into analog data signals, and output the resulting analog data signals to the plurality of data lines DL.

The gate driving circuit GDC can receive a first gate voltage corresponding to a turn-on level voltage and a second gate voltage corresponding to a turn-off level voltage along with various gate driving control signals GCS, generate gate signals, and supply the generated gate signals to the plurality of gate lines GL.

In one or more aspects, the data driving circuit DDC can be connected to the display panel 110 by a tape-automated-bonding (TAB) technique, or connected to a conductive pad such as a bonding pad of the display panel 110 by a chip-on-glass (COG) technique or a chip-on-panel (COP) technique, or connected to the display panel 110 by a chip-on-film (COF) technique.

In one or more aspects, the gate driving circuit GDC can be connected to the display panel 110 by the tape-automated-bonding (TAB) technique, or connected to a conductive pad such as a bonding pad of the display panel 110 by the chip-on-glass (COG) technique or the chip-on-panel (COP) technique, or connected to the display panel 110 by the chip-on-film (COF) technique. In one or more aspects, the gate driving circuit GDC can be disposed in the non-display area NDA of the display panel 110 by a gate-in-panel (GIP) technique. The gate driving circuit GDC can be disposed on the substrate, or connected to the substrate. In an example where the gate driving circuit GDC is implemented by the GIP technique, the gate driving circuit GDC can be disposed in the non-display area NDA of the substrate. The gate driving circuit GDC can be connected to the substrate in an example where the gate driving circuit GDC is implemented by the chip-on-glass (COG) technique, the chip-on-film (COF) technique, or the like.

In one or more aspects, at least one of the data driving circuit DDC and the gate driving circuit GDC can be disposed in the display area DA of the display panel 110. For example, at least one of the data driving circuit DDC and the gate driving circuit GDC can be disposed not to overlap with subpixels SP, or disposed to overlap with one or more, or all, of the subpixels SP, or at least respective one or more portions of one or more subpixels.

In one or more aspects, the data driving circuit DDC can be disposed in, and/or electrically connected to, but not limited to, only one side or edge (e.g., an upper portion or a lower portion) of the display panel 110. In one or more aspects, the data driving circuit DDC can be located in, and/or electrically connected to, but not limited to, two sides or edges (e.g., an upper portion and a lower portion) of the display panel 110 or at least two of four sides or edges (e.g., the upper portion, the lower portion, a left portion, and a right portion) of the display panel 110 according to driving schemes, panel design schemes, or the like.

In one or more aspects, the gate driving circuit GDC can be located in, and/or electrically connected to, but not limited to, one side or edge (e.g., a left portion or a right portion) of the display panel 110. In one or more aspects, the gate driving circuit GDC can be located in, and/or electrically connected to, but not limited to, two sides or edges (e.g., a left portion and a right portion) of the display panel 110 or at least two of four sides or edges (e.g., an upper portion, a lower portion, the left portion, and the right portion) of the display panel 110 according to driving schemes, panel design schemes, or the like.

The display controller DCTR can be implemented in a separate component from the data driving circuit DDC, or integrated with the data driving circuit DDC, so that the display controller DCTR and the data driving circuit DDC can be implemented in a single integrated circuit.

The display controller DCTR can be a timing controller used in the normal display technology or a controller or a control device capable of performing other control functions in addition to the function of the normal timing controller. In one or more aspects, the display controller DCTR can be a controller or a control device different from the timing controller, or a circuitry or a component included in the controller or the control device. The display controller DCTR can be implemented with various circuits or electronic components such as an integrated circuit (IC), a field programmable gate array (FPGA), an application specific integrated circuit (ASIC), a processor, and/or the like.

The display controller DCTR can be mounted on a printed circuit board, a flexible printed circuit, or the like, and can be electrically connected to the data driving circuit DDC and the gate driving circuit GDC through the printed circuit board, the flexible printed circuit, and/or the like.

The display controller DCTR can transmit signals to, and receive signals from, the data driving circuit DDC via one or more predefined interfaces. For example, such interfaces can include a low voltage differential signaling (LVDS) interface, an embedded clock point-point interface (EPI), a serial peripheral interface (SPI), and the like.

In one or more aspects, to further provide a touch sensing function as well as an image display function, the display device 100 can include at least one touch sensor, and a touch sensing circuit capable of detecting whether a touch event occurs by a touch object such as a finger, a pen, or the like, or of detecting a corresponding touch position, by sensing the touch sensor.

The touch sensing circuit can include a touch driving circuit TDC capable of generating and providing touch sensing data by driving and sensing the touch sensor, a touch controller TCTR capable of detecting the occurrence of a touch event or detecting a touch position (or touch coordinates) using the touch sensing data, and one or more other components.

The touch sensor can include a plurality of touch electrodes. The touch sensor can further include a plurality of touch lines for electrically connecting the plurality of touch electrodes to the touch driving circuit TDC.

In one or more aspects, the touch driving circuit TDC and the touch controller TCTR, which are included in the touch sensing circuit, can be implemented in separate devices or in one device. In one or more aspects, the touch driving circuit TDC and the data driving circuit DDC can be implemented in separate devices or in one device.

The display device 100 can further include a power supply circuit for supplying several types of power to the display driving circuit and/or the touch sensing circuit.

In one or more aspects, the display device 100 can be a mobile terminal such as a smart phone, a tablet, or the like, or a monitor, a television (TV), or the like. Further, the display device 100 can be configured with various types, sizes, and shapes to display information or images. For example, the display device 100 can be applied to mobile devices, video phones, smart watches, watch phones, wearable apparatuses, foldable apparatuses, rollable apparatuses, bendable apparatuses, flexible apparatuses, stretchable apparatuses, curved apparatuses, sliding apparatuses, variable apparatuses, electronic notebooks, e-books, portable multimedia players (PMP), personal digital assistants (PDA), MP3 players, mobile medical apparatuses, desktop PCs, laptop PCs, netbook computers, workstations, navigation apparatuses, car navigation apparatuses, vehicle display apparatuses, vehicle apparatuses, theater apparatuses, theater display apparatuses, televisions, wallpaper apparatuses, signage apparatuses, game apparatuses, notebook computers, monitors, cameras, camcorders, and home appliances, and the like.

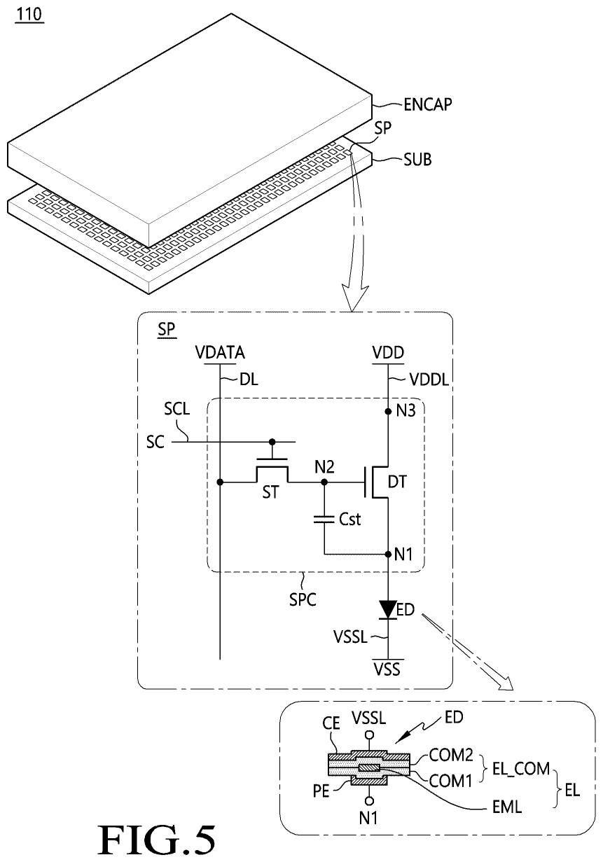

FIG. 5 illustrates an example configuration of the display panel 110 according to aspects of the present disclosure. In discussions that follow for the configuration of FIG. 5, discussions for features and configurations equal, substantially equal, or similar to the features and configurations described with reference to FIGS. 1 to 4 are omitted or briefly described for conciseness.

Referring to FIG. 5, in one or more example embodiments of the present disclosure, the display panel 110 can include a substrate SUB on which a plurality of subpixels SP are disposed, and an encapsulation layer ENCAP on the substrate SUB. The encapsulation layer ENCAP can also be referred to as an encapsulation substrate or an encapsulation part.

In an example where the display device 100 is a self-emissive display device, each of the plurality of subpixels SP disposed on the substrate SUB can include a light emitting element ED and a subpixel circuit SPC for driving the light emitting element ED.

The subpixel circuit SPC can include a plurality of transistors and at least one capacitor for driving the light emitting element ED. The subpixel circuit SPC can drive the light emitting element ED by supplying a driving current to the light emitting element ED at a predetermined time. The light emitting element ED can emit light by being driven by the driving current.

The plurality of transistors can include a driving transistor DT configured to drive the light emitting element ED and a scan transistor ST configured to be turned on or off by a scan signal SC.

The driving transistor DT can supply a driving current to the light emitting element ED.

The scan transistor ST can be configured to control an electrical state of a corresponding node in the subpixel circuit SPC or to control the state or operation of the driving transistor DT.

The at least one capacitor can include a storage capacitor Cst configured to maintain a voltage at a constant level during a display frame or a period of the display frame.

To drive at least one subpixel SP, at least one data signal VDATA, which is an image signal, and at least one scan signal SC, which is a gate signal, can be applied to the at least one subpixel SP. Further, to drive one or more subpixels SP, at least one common driving voltage including a first common driving voltage VDD and a second common driving voltage VSS can be applied to the one or more subpixels SP.

The light emitting element ED can include a pixel electrode PE, an intermediate layer EL, and a common electrode CE. The intermediate layer EL can be disposed between the pixel electrode PE and the common electrode CE.

For example, the pixel electrode PE can be an electrode disposed for each subpixel SP, and the common electrode CE can be an electrode disposed commonly in all or some of a plurality of subpixels SP. For example, the pixel electrode PE can be an anode, and the common electrode CE can be a cathode. In another example, the pixel electrode PE can be a cathode, and the common electrode CE can be an anode. Hereinafter, for convenience of explanation, discussions can be provided based on examples where the pixel electrode PE is an anode, and the common electrode CE is a cathode.

In an example where the light emitting element ED is an organic light emitting diode, the intermediate layer EL can include an emission layer EML, a first common intermediate layer COM1 between the pixel electrode PE and the emission layer EML, and a second common intermediate layer COM2 between the emission layer EML and the common electrode CE. A layer including the first common intermediate layer COM1 and the second common intermediate layer COM2 can be referred to as a common intermediate layer EL_COM.

In one or more aspects, the emission layer EML can be disposed for each subpixel SP, and the common intermediate layer EL_COM can be commonly disposed across all or some of a plurality of subpixels SP. For example, the emission layer EML and the common intermediate layer EL_COM can be commonly disposed across all or some of a plurality of subpixels SP.

For example, the emission layer EML can be disposed for each light emitting area, and the common intermediate layer EL_COM can be commonly disposed across a plurality of light emitting areas and a non-light emitting area. For example, the emission layer EML and the common intermediate layer EL_COM can be commonly disposed across a plurality of light emitting areas and a non-light emitting area.

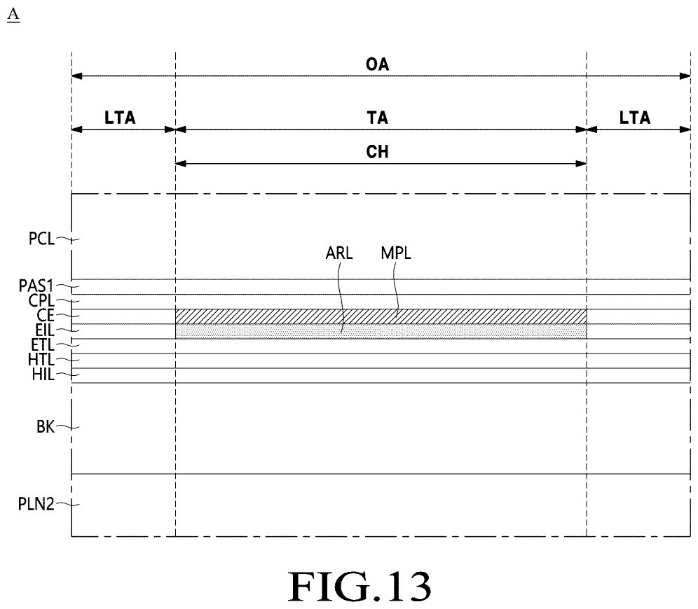

For example, the first common intermediate layer COM1 can include a hole injection layer HIL, a hole transfer layer HTL, and the like. The second common intermediate layer COM2 can include an electron transport layer ETL, an electron injection layer EIL, and the like (see FIG. 13).

The hole injection layer HIL can inject holes from the pixel electrode PE to the hole transport layer HTL, and the hole transport layer HTL can transport holes to the emission layer EML. The electron injection layer EIL can inject electrons from the common electrode CE to the electron transport layer ETL, and the electron transport layer ETL can transport electrons to the emission layer EML.

The hole injection layer HIL can be located between the pixel electrode PE and the hole transport layer HTL. A material included in the hole injection layer HIL can be selected from secondary amine compounds, tertiary amine compounds, radialene compounds, indacene compounds, metal cyanine compounds, and/or one or more combinations thereof. For example, the hole injection layer HIL can include at least one compound selected from the group of HATCN (dipyrazino[2,3-f:2′,3′-h]quinoxaline-2,3,6,7,10,11-hexacarbonitrile), MTDATA (4,4′,4″-Tris(N-3-methylphenyl-N-phenylamino)-triphenylamine), TCTA (tris(4-carbazoyl-9-yl-phenyl)amine), CuPc (copper (II) phthalocyanine), TDAPB (1,3,5-tris[4-[bis(4-methoxyphenyl)amino]phenyl]benzene), PANI (polyaniline), NPB (N,N-dinaphthyl-N,N′-diphenyl benzidine), PEDOT (poly(3,4)-ethylenedioxythiophene), N1,N1′-([1,1′-biphenyl]-4,4′-diyl)bis(N1,N4,N4-triphenylbenzene-1,4-diamine), and/or the like, but aspects of the present disclosure are not limited thereto.

The hole transport layer HTL can be located between the hole injection layer HIL and the emission layer EML. The hole transport layer HTL can include at least one compound selected from the group of MTDATA, TAPC (di-[4-(N,N-di-p-tolyl-amino)-phenyl]cyclohexane), TPD (N,N′-bis(3-methylphenyl)-N,N′-diphenylbenzidine), NPB, CBP (4,4-N,N′-dicarbazole-1,1′-biphenyl), N-([1,1′-biphenyl]-4-yl)-9,9-dimethyl-N-(4-(9-phenyl-9H-carbazole-3-yl)phenyl)-9H-fluoren-2-amine, N-(biphenyl-4-yl)-N-(4-(9-phenyl-9H-carbazole-3-yl)phenyl) biphenyl-4-amine, and/or the like, but aspects of the present disclosure are not limited thereto.

The electron transport layer ETL can be located between the emission layer EML and the electron injection layer EIL. The electron transport layer ETL can include at least one compound selected from the group consisting of Alq3 (tris(8-hydroxyquinolinato)aluminium), Liq (8-hydroxyquinolinato) lithium, PBD (2-(4-biphenylyl)-5-(4-tert-butylphenyl)-1,3,4-oxadiazole), TAZ (3-(biphenyl-4-yl)-5-(4-tert-butylphenyl)-4-phenyl-4H-1,2,4-triazole), spiro-PBD, BAlq (bis(8-hydroxy-2-methylquinoline)-(4-phenylphenoxy)aluminum), SAlq (bis(8-hydroxy-2-methylquinoline)-(triphenylsilyl)aluminium), TPBi (2,2′,2″-(1,3,5-benzinetriyl)-tris(1-phenyl-1-H-benzimidazole), oxadiazole, triazole, phenanthroline, benzoxazole, benzthiazole, ZADN (2-(4-(9,10-di-naphthalen-2-yl-anthracen-2-yl)-phenyl)-1-phenyl-1H-benzoimidazole), and/or the like, but aspects of the present disclosure are not limited thereto.

The electron injection layer EIL can be located between the electron transport layer ETL and the common electrode CE. The electron injection layer EIL can include at least one organic compound or organometallic compound selected from the group of Alq3, PBD, TAZ, spiro-PBD, BAlq, SAlq, Bphen (4,7-diphenyl-1,10-phenanthroline), and/or the like, but aspects of the present disclosure are not limited thereto. The electron injection layer EIL can include a mixture of the foregoing organic compound or organometallic compound and a metal material, or include a metal material alone. For example, a mixture of Bphen and LiF can be included in the electron injection layer EIL. In this case, for example, the metal material can include one or more selected from the group of Liq, LiF, NaF, KF, RbF, CsF, FrF, BeF₂, MgF₂, CaF₂, SrF₂, BaF₂ and RaF₂, but aspects of the present disclosure are not limited thereto. For example, a material obtained by mixing the foregoing metal material and a metal element having a low work function, such as ytterbium (Yb), calcium (Ca), strontium (Sr), barium (Ba), or lanthanum (La) can be used as a material included in the electron injection layer EIL. For example, LiF and ytterbium (Yb) can be mixed and used as a material included in the electron injection layer EIL.

For example, the common electrode CE can be electrically connected to a second common driving voltage line VSSL. A second common driving voltage VSS can be applied to the common electrode CE through the second common driving voltage line VSSL. The pixel electrode PE can be electrically connected directly or indirectly (via another transistor) to a first node N1 of the corresponding driving transistor DT of each subpixel SP. Herein, the second common driving voltage VSS can also be referred to as a “base voltage”, and the second common driving voltage line VSSL can also be referred to as a “low power supply voltage line”, a “low voltage line”, or a “base voltage line”.

Each light emitting element ED can be configured by overlapping of a pixel electrode PE, an emission layer EML in an intermediate layer EL, and a common electrode CE. A respective light emitting area can be formed by each light emitting element ED. For example, a respective light emitting area of each light emitting element ED can include an area where a pixel electrode PE, an emission layer EML in an intermediate layer EL, and a common electrode CE overlap with each other.

In an example where each light emitting element ED is an organic light emitting diode (OLED), the corresponding intermediate layer EL of each light emitting element ED can be a layer including an organic material.

The driving transistor DT can be a transistor configured to supply a driving current to the light emitting element ED. The driving transistor DT can be connected between a first common driving voltage line VDDL and the light emitting element ED.

The driving transistor DT can include a first node N1, a second node N2, and a third node N3. The first node N1 can be electrically connected to the light emitting element ED. A data signal VDATA can be applied to the second node N2. A first common driving voltage VDD delivered through the first common driving voltage line VDDL can be applied to the third node N3.

In the driving transistor DT, the second node N2 can be a gate node, the first node N1 can be a source node or a drain node, and the third node N3 can be the drain node or the source node. Hereinafter, for merely convenience of explanation, discussions can be provided based on examples where the first, second, and third nodes (N1, N2, and N3) of the driving transistor DT are source, gate, and drain nodes (or electrodes), respectively. However, aspects of the present disclosure are not limited thereto.

The scan transistor ST included in the subpixel circuit SPC illustrated in FIG. 5 can be a switching transistor for transferring a data signal VDATA, which is an image signal, to the second node N2, which is the gate node of the driving transistor DT.

The scan transistor ST can be turned on or turned off by a scan signal SC, which is a type of gate signal, applied through a scan line SCL, which is a type of gate line GL, and control an electrical connection between the second node N2 of the driving transistor DT and a data line DL. The drain electrode or source electrode of the scan transistor ST can be electrically connected to the data line DL. The source electrode or drain electrode of the scan transistor ST can be electrically connected to the second node N2 of the driving transistor DT. The gate electrode of the scan transistor ST can be electrically connected to the scan line SCL.

The storage capacitor Cst can be electrically connected between the first node N1 and the second node N2 of the driving transistor DT. The storage capacitor Cst can include a first capacitor electrode electrically connected to the first node N1 of the driving transistor DT or corresponding to the first node N1 of the driving transistor DT, and a second capacitor electrode electrically connected to the second node N2 of the driving transistor DT or corresponding to the second node N2 of the driving transistor DT.

The storage capacitor Cst can be an external capacitor intentionally designed to be located outside of the driving transistor DT, and therefore, be different from an internal capacitor such as a parasitic capacitor (e.g., a gate-source capacitor Cgs, a gate-drain capacitor Cgd) that can be formed between the first node N1 and the second node N2 of the driving transistor DT.

Each of the driving transistor DT and the scan transistor ST can be an n-type transistor or a p-type transistor.

The display panel 110 can have a top emission structure or a bottom emission structure.

In an example where the display panel 110 has the top emission structure, at least a portion of the subpixel circuit SPC can overlap with at least a portion of the light emitting element ED in the vertical direction. In this configuration, the area or size of a corresponding light emitting area can increase, and a corresponding aperture ratio can increase.

In an example where the display panel 110 has the bottom emission structure, the subpixel circuit SPC may not overlap with the light emitting element ED in the vertical direction.

The subpixel circuit SPC can have a 2T (Transistor) 1C (Capacitor) structure including two transistors (DT and ST) and one capacitor (Cst) as illustrated in FIG. 5. In one or more aspects, the subpixel circuit SPC can further include one or more transistors and/or one or more capacitors in the 2T1C structure.

For example, the subpixel circuit SPC can have an 8T1C structure including 8 transistors and 1 capacitor. In another example, the subpixel circuit SPC can have an 6T2C structure including 6 transistors and 2 capacitors. In another example, the subpixel circuit SPC can have an 7T1C structure including 7 transistors and 1 capacitor. However, aspects of the present disclosure are not limited to such specific structures.

The types and number of gate signals supplied to a subpixel SP, and/or the types and number of gate lines connected to the subpixel SP can vary depending on a structure of a corresponding subpixel circuit SPC. Further, the types and number of common driving voltages supplied to a subpixel SP can vary depending on a structure of a corresponding subpixel circuit SPC.

Referring to FIG. 5, since circuit elements (e.g., a light emitting element ED such as an organic light emitting diode (OLED) including an organic material) in each subpixel SP can be easily damaged by external moisture or oxygen, an encapsulation layer ENCAP can be disposed in the display panel 110 to prevent the external moisture or oxygen from penetrating the circuit elements (e.g., the light emitting element ED). The encapsulation layer ENCAP can be disposed such that it covers light emitting elements ED.

The encapsulation layer ENCAP can be disposed in various shapes or configurations to prevent light emitting elements ED from contacting moisture or oxygen. For example, the encapsulation layer ENCAP can include two or more layers in which one or more organic layers and one or more inorganic layers are alternately stacked, but aspects of the present disclosure are not limited thereto.

As discussed above, the display device 100 can include the one or more optical electronic devices (11 and/or 12). Hereinafter, it should be noted that although for convenience of description, the term “optical electronic device” is described, but the optical electronic device includes the first optical electronic device 11 and/or the second optical electronic device 12 unless otherwise specified. Therefore, the optical electronic device described below can correspond to the first optical electronic device 11, to the second optical electronic device 12, or to both the first optical electronic device 11 and the second optical electronic device 12.

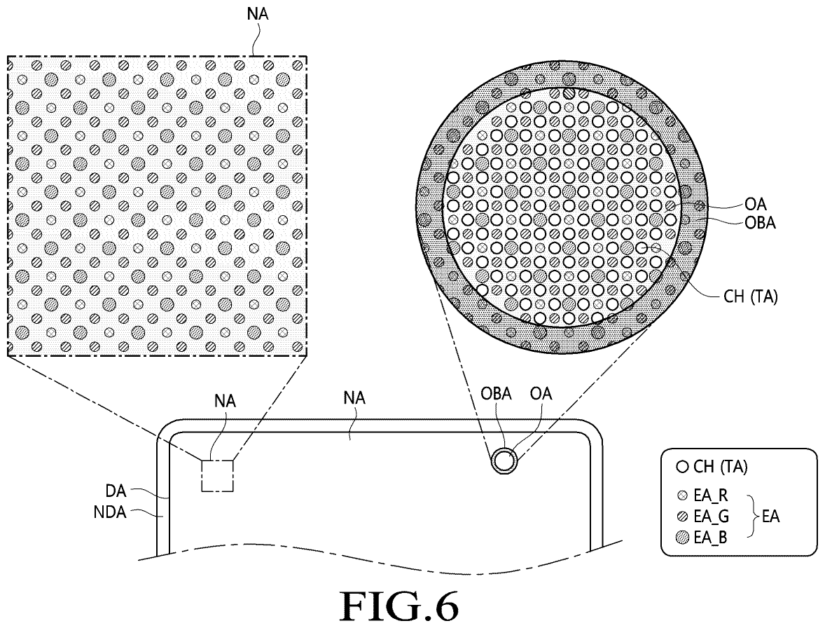

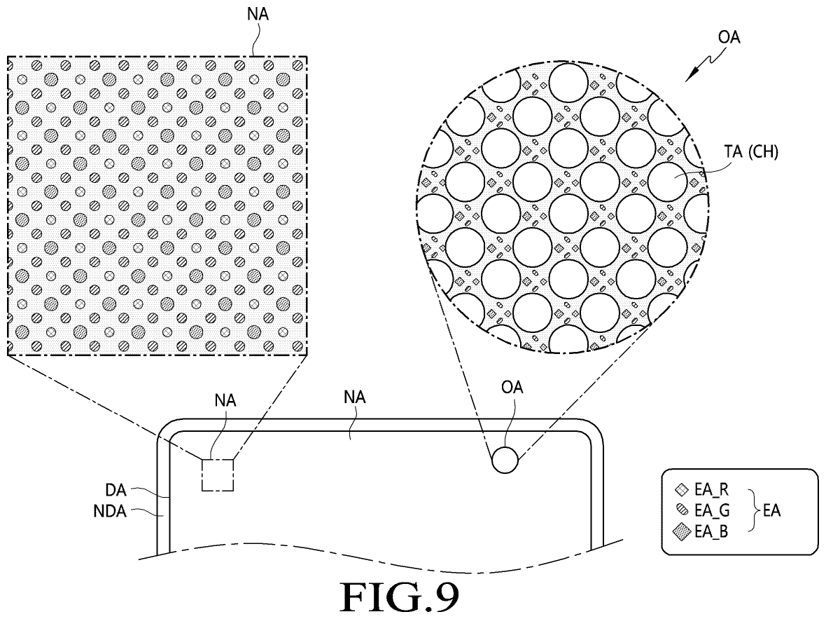

Hereinafter, a first type of optical area OA is described with reference to FIGS. 6 to 8, and a second type of optical area OA is described with reference to FIGS. 9 to 11.

The first type of optical area OA and the second type of optical area OA can be briefly described as follows.

In the structure of the first type of optical area OA, pixel circuits SPC for driving a plurality of light emitting elements ED disposed in the optical area OA can be disposed in an area around an outer edge of the optical area OA instead of being disposed in the optical area OA.

In the structure of the second type of optical area OA, pixel circuits SPC for driving a plurality of light emitting elements ED disposed in the optical area OA can be disposed in the optical area OA.

FIG. 6 illustrates an example configuration of a first type of optical area OA and a normal area NA outside of the first type of optical area in the display panel 110 according to aspects of the present disclosure. In discussions that follow for the configuration of FIG. 6, discussions for features and configurations equal, substantially equal, or similar to the features and configurations described with reference to FIGS. 1 to 5 are omitted or briefly described for conciseness.

An optical area OA can have a first type of structure. In the structure of the first type of optical area OA, an optical bezel area OBA can be disposed around an outer edge of the optical area OA. In one or more aspects, the optical bezel area OBA can be a part of the normal area NA.

Referring to FIG. 6, in one or more example embodiments of the present disclosure, the optical area OA can be an area overlapping with an optical electronic device and be an area through which light required for the operation of the optical electronic device can be transmitted.

The optical bezel area OBA can be an area located outside of the optical area OA. The normal area NA can be an area located outside of the optical bezel area OBA. The optical bezel area OBA can be an area located between the optical area OA and the normal area NA.

In an example where the optical bezel area OBA is disposed outside of a whole edge of the optical area OA, the optical bezel area OBA can have a ring shape surrounding the optical area OA.

For example, the optical area OA can have various shapes, such as a circular, an elliptical, a polygonal, or an irregular shape. The optical bezel area OBA can have various ring shapes (e.g., a circular ring shape, an elliptical ring shape, a polygonal ring shape, an irregular ring shape, or the like) surrounding the optical area OA having various shapes.

The display area DA can include a plurality of light emitting areas EA. Since the optical area OA, the optical bezel area OBA, and the normal area NA are areas included in the display area DA, each of the optical area OA, the optical bezel area OBA, and the normal area NA can include a plurality of light emitting areas EA.

For example, the plurality of light emitting areas EA can include a first color light emitting area that emits light of a first color, a second color light emitting area that emits light of a second color, and a third color light emitting area that emits light of a third color. For example, the first color, the second color, and the third color can include red, green, and blue, respectively.

Hereinafter, for convenience of description, discussions are provided based on examples where the first color is red, the second color is green, and the third color is blue. However, aspects of the present disclosure are not limited thereto.

Referring to FIG. 6, the optical area OA can be an area through light can be transmitted and be desired to have a high transmittance. To satisfy this configuration, a cathode electrode CE can include a plurality of cathode holes CH in the optical area OA. For example, in the optical area OA, the cathode electrode CE can include a plurality of cathode holes CH.

The cathode electrode CE may not include a cathode hole CH in the normal area NA. For example, in the normal area NA, the cathode electrode CE may not include a cathode hole CH.

The cathode electrode CE may not include a cathode hole CH in the optical bezel area OBA. For example, in the optical bezel area OBA, the cathode electrode CE may not include a cathode hole CH.

The plurality of cathode holes CH formed in the cathode electrode CE in the optical area OA can also be referred to as transmissive areas TA, open areas, or openings. FIG. 6 illustrates that one cathode hole CH has a circular shape, but in addition to, or instead of, the circular shape, one or more of cathode holes CH can have various shapes such as an oval, a polygon, or an irregular shape.

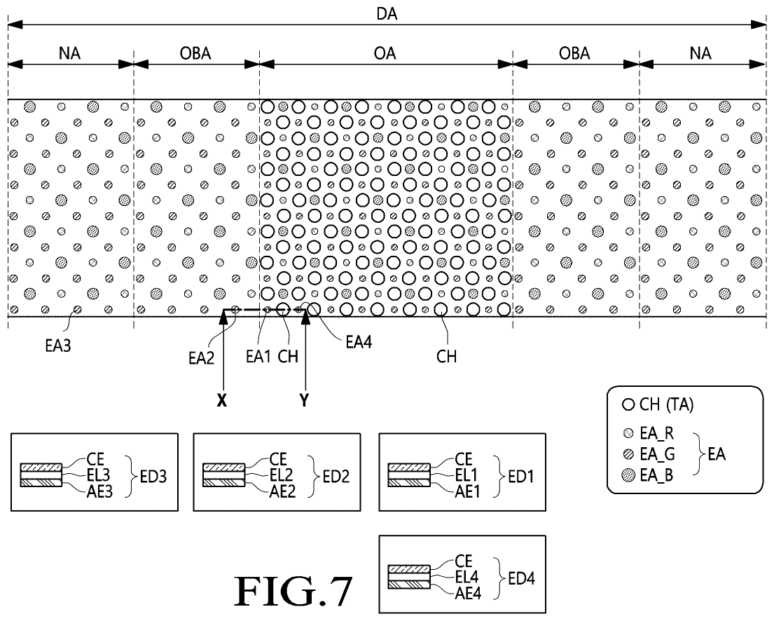

FIG. 7 is an example plan view illustrating the normal area NA, the optical bezel area OBA, and the optical area OA in the display panel 110 according to aspects of the present disclosure. In discussions that follow for the configuration of FIG. 7, discussions for features and configurations equal, substantially equal, or similar to the features and configurations described with reference to FIGS. 1 to 6 are omitted or briefly described for conciseness.

Referring to FIG. 7, in one or more example embodiments of the present disclosure, in the display panel 110, a plurality of light emitting areas EA disposed in each of the normal area NA, the optical bezel area OBA, and the optical area OA can include at least one red light emitting area EA_R, at least one green light emitting area EA_G, and at least one blue light emitting area EA_B.

Referring to FIG. 7, in one or more aspects, the cathode electrode CE included in the display panel 110 can be commonly disposed in the normal area NA, the optical bezel area OBA, and the optical area OA.

The cathode electrode CE can include a plurality of cathode holes CH, and the plurality of cathode holes CH of the cathode electrode CE can be disposed in the optical area OA.

The whole optical area OA can be an area through which light can be transmitted, and the plurality of cathode holes CH in the optical area OA can be transmissive areas TA through which light can be transmitted better. For example, the remaining area except for the plurality of cathode holes CH among areas of the optical area OA can be an area through which light can be transmitted, and the transmittance of the plurality of cathode holes CH of the optical area OA can be greater than the transmittance of the remaining area except for the plurality of cathode holes CH.

In another example, among areas of the optical area OA, the plurality of cathode holes CH can be areas through which light can be transmitted, and the remaining area except for the plurality of cathode holes CH can be an area not allowing light to be transmitted.

Referring to FIG. 7, a plurality of light emitting areas EA can include at least one first light emitting area EA1 included in the optical area OA, at least one second light emitting area EA2 that emits light of the same color as the first light emitting area EA1 and is included in the optical bezel area OBA, and at least one third light emitting area EA3 that emits light of the same color as the first light emitting area EA1 and is included in the normal area NA.

The plurality of light emitting areas EA can further include at least one fourth light emitting area EA4 that emits light of the same color as the first light emitting area EA1 and is included in the optical area OA.

In one or more aspects, the display panel 110 can include at least one first anode electrode AE1 disposed in the optical area OA, at least one second anode electrode AE2 disposed in the optical bezel area OBA, at least one third anode electrode AE3 disposed in the normal area NA, and at least one fourth anode electrode AE4 disposed in the optical area OA.

In one or more aspects, the display panel 110 can further include the cathode electrode CE commonly disposed in the normal area NA, the optical bezel area OBA, and the optical area OA.

Some of a plurality of light emitting elements ED included in the display panel 110 can include a first light emitting element ED1 configured with the first anode electrode AE1, a first intermediate layer EL1, and the cathode electrode CE, a second light emitting element ED2 configured with the second anode electrode AE2, a second intermediate layer EL2, and the cathode electrode CE, a third light emitting element ED3 configured with the third anode electrode AE3, a third intermediate layer EL3, and the cathode electrode CE, and a fourth light emitting element ED4 configured with the fourth anode electrode AE4, a fourth intermediate layer EL4, and the cathode electrode CE.

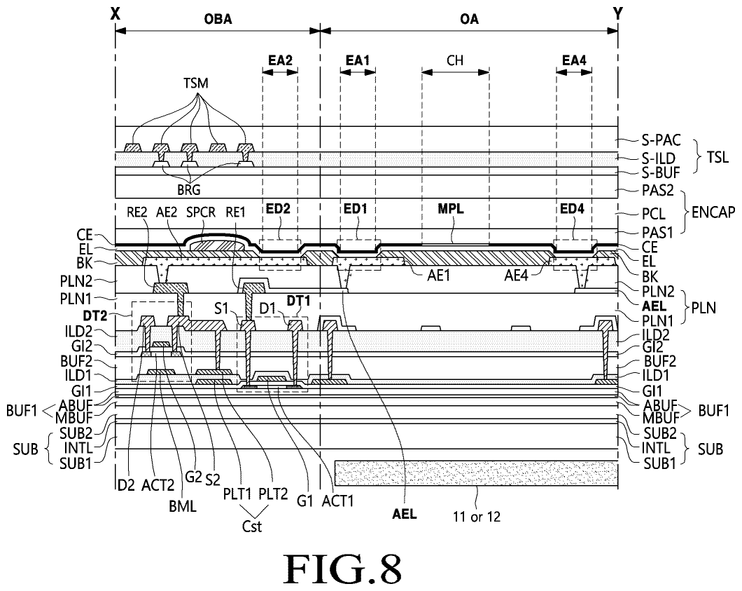

Hereinafter, a cross-sectional structure taken along line X-Y of FIG. 7 is discussed in more detail with reference to FIG. 8.

A portion indicated by line X-Y in FIG. 7 can include the first light emitting area EA1 and the fourth light emitting area EA4 included in the optical area OA, and the second light emitting area EA2 included in the optical bezel area OBA. The first light emitting area EA1, the fourth light emitting area EA4, and the second light emitting area EA2 can be light emitting areas EA that emit light of the same color.

FIG. 8 is an example cross-sectional view of the optical bezel area OBA and the optical area OA in the display panel 110 according to aspects of the present disclosure. In discussions that follow for the configuration of FIG. 8, discussions for features and configurations equal, substantially equal, or similar to the features and configurations described with reference to FIGS. 1 to 7 are omitted or briefly described for conciseness.

Referring to FIG. 8, in one or more example embodiments of the present disclosure, the display panel 110 can include a transistor part, a light emitting element part, and an encapsulation part in terms of a stack-up structure.

The transistor part can include a substrate SUB, a first buffer layer BUF1 on the substrate SUB, and various transistors (DT1, DT2, and the like), a storage capacitor Cst, and various electrodes or signal lines, which are disposed on the first buffer layer BUF.

The substrate SUB can include a first substrate SUB1 and a second substrate SUB2, and can include an intermediate film INTL between the first substrate SUB1 and the second substrate SUB2. For example, the intermediate film INTL can be an inorganic layer, and can serve to shield the penetration of moisture.

A lower shield metal BSM can be disposed on the substrate SUB. The lower shield metal BSM can be located under a first active layer ACT1 of a first driving transistor DT1.

The first buffer layer BUF1 can be in the form of a single layer or a multilayer. When the first buffer layer BUF1 is in the form of a multilayer, the first buffer layer BUF1 can include a multi-buffer layer MBUF and an active buffer layer ABUF.

Various transistors (DT1, DT2, and the like), at least one storage capacitor Cst, and various electrodes or signal lines can be disposed on the first buffer layer BUF1.

For example, two or more of the transistors (DT1, DT2, and the like) disposed on the first buffer layer BUF1 can include a same material and be located in one or more layers together. In another example, as illustrated in FIG. 8, among the transistors (DT1, DT2, and the like), a first driving transistor DT1 and a second driving transistor DT2 can include different materials and be located in different layers.

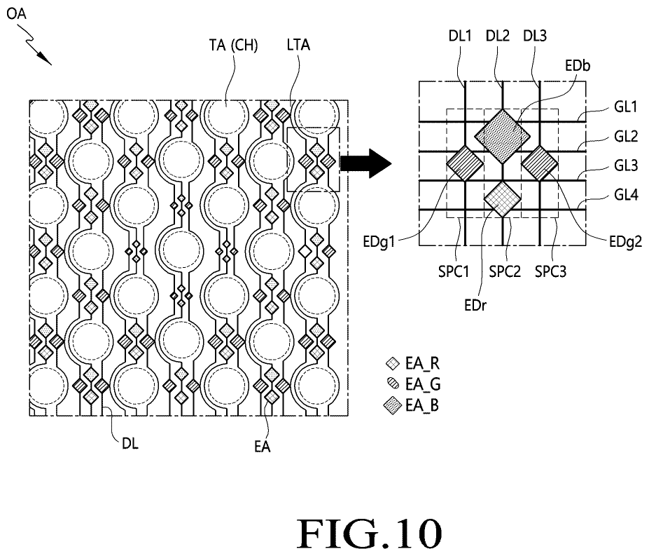

The first driving transistor DT1 can be a driving transistor included in a first pixel circuit SPC1 (see FIG. 10) for driving the first light emitting element ED1 included in the optical area OA, and the second driving transistor DT2 can be a driving transistor included in a second pixel circuit SPC2 (see FIG. 10) for driving the second light emitting element ED2 included in the optical bezel area OBA.

The formation of the first driving transistor DT1 and the second driving transistor DT2 is described below.

The first driving transistor DT1 can include a first active layer ACT1, a first gate electrode G1, a first source electrode S1, and a first drain electrode D1.

The second driving transistor DT2 can include a second active layer ACT2, a second gate electrode G2, a second source electrode S2, and a second drain electrode D2.

The second active layer ACT2 of the second driving transistor DT2 can be disposed at a location higher than the first active layer ACT1 of the first driving transistor DT1.

The first buffer layer BUF1 can be disposed under the first active layer ACT1 of the first driving transistor DT1, and a second buffer layer BUF2 can be disposed under the second active layer ACT2 of the second driving transistor DT2.

For example, the first active layer ACT1 of the first driving transistor DT1 can be located on the first buffer layer BUF1, and the second active layer ACT2 of the second driving transistor DT2 can be located on the second buffer layer BUF2. For example, the second buffer layer BUF2 can be disposed at a location higher than the first buffer layer BUF1.

The first active layer ACT1 of the first driving transistor DT1 can be disposed on the first buffer layer BUF1, and a first gate insulating layer GI1 can be disposed on the first active layer ACT1 of the first driving transistor DT1. The first gate electrode G1 of the first driving transistor DT1 can be disposed on the first gate insulating layer GI1, and a first interlayer insulating layer ILD1 can be disposed on the first gate electrode G1 of the first driving transistor DT1.

The first active layer ACT1 of the first driving transistor DT1 can include a first channel region overlapping with the first gate electrode G1, a first source connection region located on one side of the first channel region, and a first drain connection region located on the other side of the first channel region.

The second buffer layer BUF2 can be disposed on the first interlayer insulating layer ILD1.

The second active layer ACT2 of the second driving transistor DT2 can be disposed on the second buffer layer BUF2, and a second gate insulating layer GI2 can be disposed on the second active layer ACT2. The second gate electrode G2 of the second driving transistor DT2 can be disposed on the second gate insulating layer GI2, and a second interlayer insulating layer ILD2 can be disposed on the second gate electrode G2.

The second active layer ACT2 of the second driving transistor DT2 can include a second channel region overlapping with the second gate electrode G2, a second source connection region located on one side of the second channel region, and a second drain connection region located on the other side of the second channel region.

The first source electrode S1 and the first drain electrode D1 of the first driving transistor DT1 can be disposed on the second interlayer insulating layer ILD2. Further, the second source electrode S2 and the second drain electrode D2 of the second driving transistor DT2 can be disposed on the second interlayer insulating layer ILD2.

The first source electrode S1 and the first drain electrode D1 of the first driving transistor DT1 can be connected to the first source connection region and the first drain connection region of the first active layer ACT1, respectively, through holes of the second interlayer insulating layer ILD2, the second gate insulating layer GI2, the second buffer layer BUF2, the first interlayer insulating layer ILD1, and the first gate insulating layer GI1.

The second source electrode S2 and the second drain electrode D2 of the second driving transistor DT2 can be connected to the second source connection region and the second drain connection region of the second active layer ACT2, respectively, through holes of the second interlayer insulating layer ILD2 and the second gate insulating layer GI2.

It should be noted that FIG. 8 illustrates only the second driving transistor DT2 and a storage capacitor Cst included in the second pixel circuit SPC2, but one or more additional transistors are omitted in FIG. 8. Further, FIG. 8 illustrates only the first driving transistor DT1 included in the first pixel circuit SPC1, but one or more additional transistors and one or more storage capacitors Cst are omitted in FIG. 8.

Referring to FIG. 8, the storage capacitor Cst included in the second pixel circuit SPC2 can include a first capacitor electrode PLT1 and a second capacitor electrode PLT2.

The first capacitor electrode PLT1 can be electrically connected to the second gate electrode G2 of the second driving transistor DT2, and the second capacitor electrode PLT2 can be electrically connected to the second source electrode S2 of the second driving transistor DT2.

A lower metal BML can be disposed under the second active layer ACT2 of the second driving transistor DT2. The lower metal BML can be overlapped with all or a portion of the second active layer ACT2.

For example, the lower metal BML can be electrically connected to the second gate electrode G2. In another example, the lower metal BML can act as a light shield for shielding light entering from layers thereunder. In this configuration, the lower metal BML can be electrically connected to the second source electrode S2.

The first driving transistor DT1 can be a transistor for driving the first light emitting element ED1 disposed in the optical area OA, but be disposed in the optical bezel area OBA.

The second driving transistor DT2 can be a transistor for driving the second light emitting element ED2 disposed in the optical bezel area OBA, and be disposed in the optical bezel area OBA.

At least one planarization layer PLN can be disposed on the first driving transistor DT1 and the second driving transistor DT2. The at least one planarization layer PLN can include a first planarization layer PLN1 and a second planarization layer PLN2 disposed on the first planarization layer PLN1.

The first planarization layer PLN1 can be disposed on the first driving transistor DT1 and the second driving transistor DT2. For example, the first planarization layer PLN1 can be disposed on the first source electrode S1 and the first drain electrode D1 of the first driving transistor DT1 and the second source electrode S2 and the second drain electrode D2 of the second driving transistor DT2.

A first relay electrode RE1 and a second relay electrode RE2 can be disposed on the first planarization layer PLN1.

For example, the first relay electrode RE1 can be an electrode for relaying an electrical connection between the first source electrode S1 of the first driving transistor DT1 and the first anode electrode AE1 of the first light emitting element ED1. The second relay electrode RE2 can be an electrode for relaying an electrical connection between the second source electrode S2 of the second driving transistor DT2 and the second anode electrode AE2 of the second light emitting element ED2.

The first relay electrode RE1 can be electrically connected to the first source electrode S1 of the first driving transistor DT1 through a hole of the first planarization layer PLN1. The second relay electrode RE2 can be electrically connected to the second source electrode S2 of the second driving transistor DT2 through another hole of the first planarization layer PLN1.

The first relay electrode RE1 and the second relay electrode RE2 can be disposed in the optical bezel area OBA.

In one or more aspects, an anode extension line AEL can be connected to the first relay electrode RE1 and extend from the optical bezel area OBA to the optical area OA. The anode extension line AEL can be included in the planarization layer PLN.

The anode extension line AEL can be a metal layer located on the first relay electrode RE1 and include a transparent material.

The second planarization layer PLN2 can be disposed such that it covers the first relay electrode RE1, the second relay electrode RE2, and the anode extension line AEL.

The light emitting element part can be located on the second planarization layer PNL2.

The light emitting element part can include the first light emitting element ED1, the second light emitting element ED2, and the fourth light emitting element ED4 formed on the second planarization layer PNL2.

The first light emitting element ED1 and the fourth light emitting element ED4 can be disposed in the optical area OA, and the second light emitting element ED2 can be disposed in the optical bezel area OBA.

In the configuration of FIG. 8, the first light emitting element ED1, the second light emitting element ED2, and the fourth light emitting element ED4 can be, for example, light emitting elements that emit light of the same color. In one or more aspects, the first light emitting element ED1, the second light emitting element ED2, and the fourth light emitting element ED4 can have respective intermediate layers EL or have a common intermediate layer EL. Hereinafter, for convenience of description, discussions are provided based on examples where the first light emitting element ED1, the second light emitting element ED2, and the fourth light emitting element ED4 have a common intermediate layer EL.

Referring to FIG. 8, the first light emitting element ED1 can be configured in an area where the first anode electrode AE1, the intermediate layer EL, and the cathode electrode CE overlap with each other. The second light emitting element ED2 can be configured in an area where the second anode electrode AE2, the intermediate layer EL, and the cathode electrode CE overlap with each other. The fourth light emitting element ED4 can be configured in an area where the fourth anode electrode AE4, the intermediate layer EL, and the cathode electrode CE overlap with each other.

The first anode electrode AE1, the second anode electrode AE2, and the fourth anode electrode AE4 can be disposed on the second planarization layer PLN2.

The second anode electrode AE2 can be connected to the second relay electrode RE2 through a hole of the second planarization layer PLN2.

The first anode electrode AE1 can be connected to the anode extension line AEL extending from the optical bezel area OBA to the optical area OA through another hole of the second planarization layer PLN2.

The fourth anode electrode AE4 can be connected to another anode extension line AEL extending from the optical bezel area OBA to the optical area OA through another hole of the second planarization layer PLN2.

For example, the another anode extension line AEL can be electrically connected to the fourth anode electrode AE4 different from the first anode electrode AE1. For example, the anode extension lines AEL can be electrically connected to the first anode electrode AE1 of the first light emitting element ED1 and the fourth anode electrode AE4 of the fourth light emitting element ED4, respectively. For example, at least one of the anode extension lines AEL can overlap with a cathode hole CH located between the first light emitting element ED1 and the fourth light emitting element ED4 among a plurality of cathode holes CH.

A bank BK can be disposed on the first anode electrode AE1, the second anode electrode AE2, and the fourth anode electrode AE4.

The bank BK can include a plurality of bank holes. For example, a portion of the first anode electrode AE1, a portion of the second anode electrode AE2, and a portion of the fourth anode electrode AE4 can be exposed through the plurality of bank holes, respectively. For example, the plurality of bank holes formed in the bank BK can overlap with the portion of the first anode electrode AE1, the portion of the second anode electrode AE2, and the portion of the fourth anode electrode AE4, respectively.

The intermediate layer EL can be disposed on the bank BK. The intermediate layer EL can be disposed in the display area and contact the respective portion of the first anode electrode AE1, the respective portion of the second anode electrode AE2, and the respective portion of the fourth anode electrode AE4 through the plurality of bank holes.

At least one spacer SPCR can be present between the intermediate layer EL and the bank BK.

The cathode electrode CE can be disposed on the intermediate layer EL in the display area. The cathode electrode CE can include a plurality of cathode holes CH. The plurality of cathode holes CH formed in the cathode electrode CE can be disposed in the optical area OA.

A plurality of metal patterning layers MPL can be disposed in the plurality of cathode holes CH. The plurality of metal patterning layers MPL can include a cathode patterning material (CPM).

The cathode patterning material (CPM) can include a non-metallic material. For example, the cathode patterning material (CPM) can include an organic compound as a non-metallic material. The cathode patterning material (CPM) can be an organic compound including a halogen element.

The halogen element can be fluorine (F), bromine (Br), chlorine (Cl), or iodine (I). For example, the cathode patterning material (CPM) can include at least one halogen element.

The organic compound can be a substituted or unsubstituted chain compound or a substituted or unsubstituted ring compound. For example, the organic compound can be an unsubstituted chain compound or an unsubstituted ring compound. Further, the organic compound can be a chain compound substituted with a hetero element or a ring compound substituted with a hetero element. The hetero element can be nitrogen (N), oxygen (O), sulfur(S), phosphorus (P), or silicon (Si).

The ring compound can include a single ring and a multi-ring compound. The ring compound can include an aromatic and an aliphatic ring compound.

The cathode patterning material (CPM) can include at least one fluorine (F) element. For example, the cathode patterning material (CPM) can include one, two, three, four, or more fluorine elements.

The metal patterning layer MPL can be disposed in the optical area OA. The metal patterning layer MPL can contact at least a portion of the cathode electrode CE.

The metal patterning layer MPL can be disposed in a transmissive area TA in the optical area OA. For example, the metal patterning layer MPL can be disposed in a path through which light can be transmitted.

The cathode hole CH illustrated in FIG. 8 can be a cathode hole located between the first light emitting area EA1 and the fourth light emitting area EA4.

In one or more aspects, referring to FIG. 8, a capping layer can be disposed on the cathode electrode CE. The capping layer can be located on the cathode electrode CE and cover the cathode hole CH. The capping layer can have a relatively great refractive index. For example, the capping layer can have a refractive index greater than that of the cathode electrode CE. The capping layer can improve the light extraction efficiency of extracting light emitted from light emitting elements ED to the outside. Since the capping layer is located on the cathode electrode CE, the resonance efficiency of a micro-resonance structure can be improved, and thereby, the light extraction efficiency of the display device 100 can be improved.

The capping layer can be an organic capping layer or an inorganic capping layer. The capping layer can be in the form of a single layer or a multilayer. In an example where the capping layer is in the form of a single layer, the capping layer can include either an organic capping layer or an inorganic capping layer. In an example where the capping layer is in the form of a multilayer, the capping layer can include an organic capping layer and an inorganic capping layer. For example, the organic capping layer can be disposed on the cathode electrode CE such that the organic capping layer contacts the cathode electrode CE, and the inorganic capping layer can be disposed on the organic capping layer such that the inorganic capping layer contacts the organic capping layer. The organic capping layer can have a refractive index greater than that of the inorganic capping layer. It should be noted that when a refractive index difference is present between the organic capping layer and the inorganic capping layer, light extraction efficiency can be improved through an interface having the refractive index difference in a path in which light is emitted.

The organic capping layer can include a low-molecular-weight material capable of being deposited. For example, the organic capping layer can be an organic material included in the light emitting element ED or be a material selected from one or more other materials having a high refractive index that does not affect the light emitting element ED. For example, the organic capping layer can include at least one compound selected from the group of PEDOT, TPD, MTDATA, MTDAB, BPPM (4,4′-bis[N,N-bis(3-methylphenyl)-amino]-diphenyl-methane), CBP, TCTA, TPBI, TAZ, and/or the like, but aspects of the present disclosure are not limited thereto.

The inorganic capping layer can include at least one of one or more oxides such as aluminum oxide (AlOx), titanium oxide (TiOx), tantalum oxide (TaOx), hafnium oxide (HfOx), zinc oxide (ZnOx), silicon oxide (SiOx), silicon nitride (SiNx), silicon oxynitride (SiOxNy), and one or more fluorides such as magnesium fluoride (MgFx) and lithium fluoride (LiFx), but aspects of the present disclosure are not limited thereto.

Referring to FIG. 8, the encapsulation part can be located on the cathode electrode CE. The encapsulation part can include an encapsulation layer ENCAP disposed on the cathode electrode CE.

The encapsulation layer ENCAP can be a layer for preventing moisture or oxygen from penetrating into the light emitting elements (ED1, ED2 and ED4) disposed under the encapsulation layer ENCAP. In particular, the encapsulation layer ENCAP can prevent moisture or oxygen from penetrating into the intermediate layer EL that can include an organic layer. For example, the encapsulation layer ENCAP can be in the form of a single layer or a multilayer.

The encapsulation layer ENCAP can include a first encapsulation layer PAS1, a second encapsulation layer PCL, and a third encapsulation layer PAS2. For example, the first encapsulation layer PAS1 and the third encapsulation layer PAS2 can be inorganic layers, and the second encapsulation layer PCL can be an organic layer.

Since the second encapsulation layer PCL includes an organic layer, the second encapsulation layer PCL can also serve as a planarization layer.

In one or more aspects, the display panel 110 can include a touch sensor embedded into the display panel 110. In this configuration, the display panel 110 can include a touch sensor part TSL disposed on the encapsulation layer ENCAP.

The touch sensor part TSL can include touch sensor metals TSM and bridge metals BRG, and can further include insulating layers such as a sensor buffer layer S-BUF, a sensor interlayer insulating layer S-ILD, and a sensor protection layer S-PAC.

The sensor buffer layer S-BUF can be disposed on the encapsulation layer ENCAP. The bridge metals BRG can be disposed on the sensor buffer layer S-BUF, and the sensor interlayer insulating layer S-ILD can be disposed on the bridge metals BRG.

The touch sensor metals TSM can be disposed on the sensor interlayer insulating layer S-ILD. One or more of the touch sensor metals TSM can be connected to corresponding one or more bridge metals BRG through one or more holes of the sensor interlayer insulating layer S-ILD.

The touch sensor metals TSM and the bridge metals BRG can be disposed in the optical bezel area OBA. The touch sensor metals TSM and the bridge metals BRG can be disposed not to overlap with the second light emitting area EA2 of the optical bezel area OBA.

A plurality of touch sensor metals TSM can form one touch electrode (or one touch electrode line (or array)), and be disposed in a mesh form to be electrically connected to each other. One or more of the touch sensor metals TSM and the remaining one or more touch sensor metals TSM can be electrically connected to each other through at least one bridge metal BRG to form one touch electrode (or one touch electrode line (or array)).

The sensor protection layer S-PAC can be disposed such that it covers the touch sensor metals TSM and the bridge metals BRG.

In one or more aspects, in an example where the touch sensor is embedded into the display panel 110, a corresponding portion of at least one of the touch sensor metals TSM located on the encapsulation layer ENCAP in the display area DA can extend along an outer inclined surface of the encapsulation layer ENCAP, and be electrically connected to a pad located further outwardly than the outer inclined surface of the encapsulation layer ENCAP. For example, the pad can be disposed in the non-display area NDA, and be a metal pattern to which the touch driving circuit TDC is electrically connected.

In one or more aspects, the display panel 110 can include the bank BK located on the first anode electrode AE1 and having a bank hole exposing a portion of the first anode electrode AE1, and the intermediate layer EL located on the bank BK and contacting the portion of the first anode electrode AE1 exposed through the bank hole.

The bank hole of the bank BK may not be overlapped with a plurality cathode holes CH. For example, the bank BK may not be depressed or perforated at areas where the cathode holes CH are located. Accordingly, at the areas where the cathode holes CH are located, the second planarization layer PLN2 and the first planarization layer PLN1 located under the bank BK may not also be depressed or perforated.

An upper surface of the bank BK located under the plurality of cathode holes CH can be in a flat state, not being damaged, and this configuration can mean that one or more insulating layers or one or more metal patterns (e.g., at least one electrode, at least one line, at least one emission layer EML, and/or the like) located under the cathode electrode CE are not damaged by a process of forming a plurality of cathode holes CH in the cathode electrode CE.

The process of forming a plurality of cathode holes CH in the cathode electrode CE is briefly described as follows. After a specific mask pattern is deposited at locations where the plurality of cathode holes CH are to be disposed, a cathode electrode material can be deposited thereon. Accordingly, the cathode electrode material can be deposited only in an area where the specific mask pattern is not present, and thereby, the cathode electrode CE having the plurality of cathode holes CH can be formed.

For example, the specific mask pattern can include a cathode patterning material (CPM). The cathode electrode material can include a magnesium-silver (Mg—Ag) alloy.

In one or more aspects, the display panel 110 can include the first driving transistor DT1 disposed in the optical bezel area OBA to drive the first light emitting element ED1 disposed in the optical area OA, and the second driving transistor DT2 disposed in the optical bezel area OBA to drive the second light emitting element ED2 disposed in the optical bezel area OBA.

The first active layer ACT1 of the first driving transistor DT1 and the second active layer ACT2 of the second driving transistor DT2 can include different semiconductor materials.

For example, the second active layer ACT2 of the second driving transistor DT2 can include an oxide semiconductor material. For example, the oxide semiconductor material can include indium gallium zinc oxide (IGZO), indium gallium zinc tin oxide (IGZTO), zinc oxide (ZnO), cadmium oxide (CdO), indium oxide (InO), zinc tin oxide (ZTO), zinc indium tin oxide (ZITO), or the like.

For example, the first active layer ACT1 of the first driving transistor DT1 can include a different semiconductor material from the second active layer ACT2 of the second driving transistor DT2.

For example, the first active layer ACT1 of the first driving transistor DT1 can include a silicon-based semiconductor material. For example, the silicon-based semiconductor material can include a low-temperature polycrystalline silicon (LTPS), or the like.

The optical area OA can overlap with an optical electronic device. The optical bezel area OBA may not overlap with the optical electronic device. In one or more aspects, a portion of the optical bezel area OBA can overlap with the optical electronic device.

The cross-sectional structure of the normal area NA can be the same as the cross-sectional structure of the optical bezel area OBA. However, the first pixel circuit SPC1 disposed in the optical bezel area OBA to drive the first light emitting element ED1 disposed in the optical area OA may not be disposed in the normal area NA.

In one or more aspects, transistors (DT and ST) and storage capacitors Cst may not be disposed in the first type of optical area OA according to FIGS. 6 to 8. For example, two or more light emitting elements ED can be disposed in the first type of optical area OA, and two or more light emitting elements ED can also be disposed in the optical bezel area OBA, which is an area around an outer edge of the first type of optical area OA. Further, transistors (DT and ST) and storage capacitors Cst may not be disposed in the first type of optical area OA, and transistors (DT and ST) and storage capacitors Cst can be disposed in the optical bezel area OBA, which is an area around an outer edge of the first type of optical area OA.

FIG. 9 illustrates an example configuration of a second type of optical area OA and a normal area NA around an edge of the second type of optical area OA in the display panel 110 according to aspects of the present disclosure. In discussions that follow for the configuration of FIG. 9, discussions for features and configurations equal, substantially equal, or similar to the features and configurations described with reference to FIGS. 1 to 8 are omitted or briefly described for conciseness.

Referring to FIG. 9, in one or more example embodiments of the present disclosure, the display area DA can include an optical area OA. In an example where the optical area OA has a second type of structure, the optical area OA can include a plurality of transmissive areas TA and a low-transmissive area LTA. Here, the second type of structure can also referred to as a hole type of structure. As an example, the display area DA can include a transmissive area in which light is transmitted and a normal area located outside of the transmissive area.

In the optical area OA, the low-transmissive area LTA can be an area except for the plurality of transmissive areas TA. The low-transmissive area LTA can include a plurality of light emitting areas EA. A plurality of light emitting elements ED for the plurality of light emitting areas EA can be disposed in the low-transmissive area LTA.

Further, a plurality of pixel circuits SPC for driving the plurality of light emitting elements ED can be disposed in the low-transmissive area LTA. For example, the plurality of pixel circuits SPC can be disposed in the optical area OA. This configuration is different from the configuration of the first type of optical area OA in FIGS. 6 to 8 in which a plurality of pixel circuits SPC are not disposed in optical area OA.

For example, the low-transmissive area LTA in the optical area OA can be, for example, an area not allowing light to be transmitted. In another example, the low-transmissive area LTA in the optical area OA can be an area allowing light to be transmitted at a low transmittance.

In the optical area OA, the transmittance of the low-transmissive area LTA can be less than the transmittance of the transmissive areas TA. However, the transmittance of the low-transmissive area LTA in the optical area OA can be greater than the transmittance of the normal area NA.

The arrangement of light emitting areas EA in the optical area OA can be the same as the arrangement of light emitting areas EA in the normal area NA, and can also be the same as the arrangement of light emitting areas EA in the optical area OA.

The cathode electrode CE can be commonly disposed in the normal area NA and the optical area OA, and the cathode electrode CE can include a plurality of cathode holes CH in the optical area OA. The plurality of cathode holes CH of the cathode electrode CE can correspond to the transmissive areas TA in the optical area OA.

Since the optical area OA includes the plurality of transmissive areas TA, the optical area OA can have a greater transmittance than the normal area NA. All or a portion of the optical area OA can overlap with an optical electronic device.

FIG. 10 is an example plan view of the second type of optical area OA in the display panel 110 according to aspects of the present disclosure. In discussions that follow for the configuration of FIG. 10, discussions for features and configurations equal, substantially equal, or similar to the features and configurations described with reference to FIGS. 1 to 9 are omitted or briefly described for conciseness.

Referring to FIG. 10, in one or more example embodiments of the present disclosure, in the structure of the second type of optical area OA, the optical area OA can include a low-transmissive area LTA and transmissive areas TA except for the low-transmissive area LTA.

The low-transmissive area LTA can include a plurality of light emitting areas EA.

Each light emitting element ED can be configured in a corresponding one of the plurality of light emitting areas EA.

Pixel circuits SPC for driving the light emitting elements ED can be disposed in the low-transmissive area LTA.

In the second type of optical area OA, the light emitting elements ED and the pixel circuits SPC can partially overlap with each other.

In the structure of the second type of optical area OA, data lines (e.g., DL1, DL2, and DL3) and gate lines (e.g., GL1, GL2, GL3, and GL4) can pass through the optical area OA.

In the optical area OA, the data lines (e.g., DL1, DL2, and DL3) can be disposed such that the data lines (e.g., DL1, DL2, and DL3) avoid transmissive areas TA corresponding to cathode holes CH and extend in the row direction (or the column direction).

In the optical area OA, the gate lines (e.g., GL1, GL2, GL3, and GL4) can be disposed such that the gate lines (e.g., GL1, GL2, GL3, and GL4) avoid transmissive areas TA corresponding to cathode holes CH and extend in the column direction (or the row direction).

The data lines (e.g., DL1, DL2, and DL3) and the gate lines (e.g., GL1, GL2, GL3, and GL4) can be connected to pixel circuits (e.g., SPC1, SPC2, and SPC3) disposed in the optical area OA.

For example, four light emitting elements (EDr, EDg1, EDg2, and EDb) can be disposed in a low-transmissive area LTA between four adjacent transmissive areas TA. The four light emitting elements (EDr, EDg1, EDg2, and EDb) can include one red light emitting element EDr, two green light emitting elements (EDg1 and EDg2), and one blue light emitting element EDb.

For example, a pixel circuit SPC1 for driving one red light emitting element EDr can be connected to a first data line DL1 and a first gate line GL1. A pixel circuit SPC2 for driving two green light emitting elements (EDg1 and EDg2) can be connected to a second data line DL2, a second gate line GL2, and a third gate line GL3. A pixel circuit SPC3 for driving one blue light emitting element EDb can be connected to a third data line DL3 and a fourth gate line GL4.

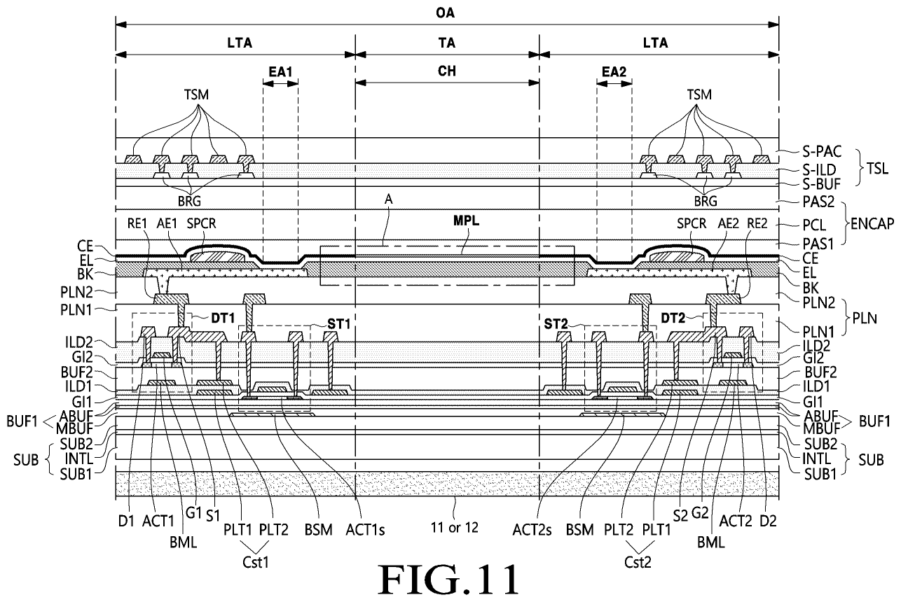

FIG. 11 is an example cross-sectional view of the second type of optical area OA in the display panel 110 according to aspects of the present disclosure. In discussions that follow for the configuration of FIG. 11, discussions for features and configurations equal, substantially equal, or similar to the features and configurations described with reference to FIGS. 1 to 10 are omitted or briefly described for conciseness.

In the cross-sectional structure of FIG. 11, metal layers and insulating layers can be the same as those in the cross-sectional structure of FIG. 8. Therefore, discussions for the cross-sectional structure of FIG. 11 are provided by focusing on different features from the cross-sectional structure of FIG. 8.

Referring to FIG. 11, in one or more example embodiments of the present disclosure, an optical electronic device can be disposed to be overlapped with all or a portion of the optical area OA. For example, the optical electronic device can be the first optical electronic device 11 and/or the second optical electronic device 12 as discussed above. The optical electronic device can be located under the substrate SUB and overlapped with at least a portion of the transmissive area.

A first light emitting element ED1 and a second light emitting element ED2 can be disposed in the optical area OA. A first light emitting area EA1 formed by the first light emitting element ED1 and a second light emitting area EA2 formed by the second light emitting element ED2 can be light emitting areas that emit light of the same color.

Referring to FIG. 11, areas where the first light emitting element ED1 and the second light emitting element ED2 are disposed can be a low-transmissive area LTA, and a transmissive area TA can be disposed between the first light emitting element ED1 and the second light emitting element ED2. For example, the transmissive area TA can be disposed between the first light emitting area EA1 formed by the first light emitting element ED1 and the second light emitting area EA2 formed by the second light emitting element ED2.

A pixel circuit SPC can be configured to drive the first light emitting element ED1, and be disposed to overlap with all or a portion of the first light emitting element ED1 in the optical area OA.

The pixel circuit SPC for driving the first light emitting element ED1 can include a first driving transistor DT1, a first scan transistor ST1, and a first storage capacitor Cst1.

A pixel circuit SPC can be configured to drive the second light emitting element ED2, and be disposed to overlap with all or a portion of the second light emitting element ED2 in the optical area OA.

The pixel circuit SPC for driving the second light emitting element ED2 can include a second driving transistor DT2, a second scan transistor ST2, and a second storage capacitor Cst2.

The first driving transistor DT1 can include a first active layer ACT1, a first gate electrode G1, a first source electrode S1, and a first drain electrode D1.

The first light emitting element ED1 can be configured in an area where a first anode electrode AE1, an intermediate layer EL, and a cathode electrode CE overlap with each other.

The first source electrode S1 of the first driving transistor DT1 can be connected to the first anode electrode AE1 through a first relay electrode RE1.

The first storage capacitor Cst1 can include a first capacitor electrode PLT1 and a second capacitor electrode PLT2.

The first source electrode S1 of the first driving transistor DT1 can be connected to the second capacitor electrode PLT2 of the first storage capacitor Cst1.

The first gate electrode G1 of the first driving transistor DT1 can be connected to the first capacitor electrode PLT1 of the first storage capacitor Cst1.

An active layer ACT1s of the first scan transistor ST1 can be located on a first buffer layer BUF1 and be located lower than the first active layer ACT1 of the first driving transistor DT1.

A semiconductor material included in the active layer ACT1s of the first scan transistor ST1 can be different from a semiconductor material included in the first active layer ACT1 of the first driving transistor DT1. For example, the semiconductor material included in the first active layer ACT1 of the first driving transistor DT1 can be an oxide semiconductor material, and the semiconductor material included in the active layer ACT1s of the first scan transistor ST1 can be a silicon-based semiconductor material (e.g., a low-temperature polycrystalline silicon (LTPS), or the like).

The second driving transistor DT2 can include a second active layer ACT2, a second gate electrode G2, a second source electrode S2, and a second drain electrode D2.

The second light emitting element ED2 can be configured in an area where a second anode electrode AE2, the intermediate layer EL, and the cathode electrode CE overlap with each other.

The second source electrode S2 of the second driving transistor DT2 can be connected to the second electrode AE2 through a second relay electrode RE2.

The second storage capacitor Cst2 can include a first capacitor electrode PLT1 and a second capacitor electrode PLT2.

The second source electrode S2 of the second driving transistor DT2 can be connected to the second capacitor electrode PLT2 of the second storage capacitor Cst2.

The second gate electrode G2 of the second driving transistor DT2 can be connected to the first capacitor electrode PLT1 of the second storage capacitor Cst2.

An active layer ACT2s of the second scan transistor ST2 can be located on the first buffer layer BUF1 and be located lower than the second active layer ACT2 of the second driving transistor DT2.

A semiconductor material included in the active layer ACT2s of the second scan transistor ST2 can be different from a semiconductor material included in the second active layer ACT2 of the second driving transistor DT2. For example, the semiconductor material included in the second active layer ACT2 of the second driving transistor DT2 can be an oxide semiconductor material, and the semiconductor material included in the active layer ACT2s of the second scan transistor ST2 can be a silicon-based semiconductor material (e.g., a low-temperature polycrystalline silicon (LTPS), or the like).

A plurality of cathode holes CH formed in the cathode electrode CE can be located such that the plurality of cathode holes CH correspond to transmissive areas TA in the optical area OA.

A plurality of metal patterning layers MPL can be disposed in the plurality of cathode holes CH. The plurality of metal patterning layers MPL can include one or more cathode patterning materials (CPM).

The metal patterning layer MPL can be disposed in the optical area OA. The metal patterning layer MPL can contact at least a portion of the cathode electrode CE.

The metal patterning layer MPL can be disposed in one or more transmissive areas TA in the optical area OA. For example, the metal patterning layer MPL can be disposed in a path through which light can be transmitted.

In one or more aspects, referring to FIG. 11, a capping layer CPL (see FIG. 13) can be disposed between the cathode electrode CE and an encapsulation layer ENCAP. The capping layer can be located on the cathode electrode CE and cover one or more cathode holes CH. The capping layer can improve the light extraction efficiency of extracting light emitted from light emitting elements ED to the outside. Since the capping layer is located on the cathode electrode CE, the resonance efficiency of a micro-resonance structure can be improved, and thereby, the light extraction efficiency of the display device 100 can be improved. The capping layer can be in the form of a single layer or a multilayer, as described above in FIG. 8. The capping layer can be an organic capping layer and/or an inorganic capping layer.

In one or more aspects, the display panel 110 can include a bank BK located on the first anode electrode AE1 and having a bank hole exposing a portion of the first anode electrode AE1, and the intermediate layer EL located on the bank BK and contacting the portion of the first anode electrode AE1 exposed through the bank hole.

The bank hole formed in the bank BK may not be overlapped with cathode holes CH.

An upper surface of the bank BK located under the plurality of cathode holes CH can be flat without being depressed or etched. For example, the bank BK may not be depressed or perforated at places where the cathode holes CH are located. Accordingly, at the places where the cathode holes CH are located, a second planarization layer PLN2 and a first planarization layer PLN1 located under the bank BK may not be depressed or perforated.

As the upper surface of the bank BK located under the plurality of cathode holes CH is formed to be flat, one or more insulating layers, one or more metal patterns (e.g., at least one electrode, at least one lines, at least one emission layer EML, and/or the like) located under the cathode electrode CE may not be damaged by a process of forming a plurality of cathode holes CH in the cathode electrode CE.

In one or more aspects, transistors (DT and ST) and storage capacitors Cst can be disposed in the second type of optical area OA according to FIGS. 9 to 11. According to the second type of optical area OA, two or more light emitting elements ED can be disposed in the optical area OA. For example, in the second type of optical area OA, two or more light emitting elements ED can be disposed in the low-transmissive area LTA in the optical area OA. Further, in the second type of optical area OA, transistors (DT and ST) and storage capacitors Cst can be disposed in the optical area OA. For example, in the second type of optical area OA, transistors (DT and ST) and storage capacitors Cst can be disposed in the low-transmissive area LTA in the optical area OA.

In one or more aspects, the intermediate layer EL or the capping layer can directly contact at least one surface of the metal patterning layer MPL in a cathode hole CH of the transmissive area TA. In this configuration, since the intermediate layer EL and the metal patterning layer MPL and/or the metal patterning layer MPL and the capping layer include organic materials of different series, a phenomenon can occur in which an interface between the intermediate layer EL and the metal patterning layer MPL and/or an interface between the metal patterning layer MPL and the capping layer is separated or peeled off. Since the metal patterning layer MPL includes an organic material having a low surface energy characteristic, adhesion between the intermediate layer EL and the metal patterning layer MPL and/or adhesion between the metal patterning layer MPL and the capping layer can be reduced by the low surface energy characteristic of the metal patterning layer MPL. Accordingly, in one or more aspects, the display device 100 can include an adhesion reinforcing layer including an adhesion reinforcement material on at least one surface of the metal patterning layer MPL. Thereby, the display device 100 can provide an advantage of increasing adhesion between the intermediate layer EL and the metal patterning layer MPL and/or the metal patterning layer MPL and the capping layer.

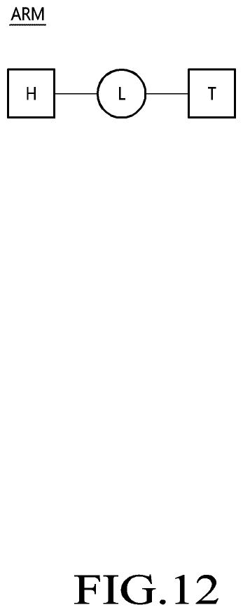

FIG. 12 illustrates an example structure of an adhesion reinforcement material included in an adhesion reinforcing layer of the display device 100 according to aspects of the present disclosure. In discussions that follow for the configuration of FIG. 12, discussions for features and configurations equal, substantially equal, or similar to the features and configurations described with reference to FIGS. 1 to 11 are omitted or briefly described for conciseness.

Referring to FIG. 12, in one or more example embodiments of the present disclosure, an adhesion reinforcement material ARM can include a head portion H and a tail portion T. The adhesion reinforcement material ARM can further include a linker L connecting the head portion H and the tail portion T to each other. In this configuration, the linker L can be a direct bond, a substituted or unsubstituted C₁-C₂₀ alkyl group, or a substituted or unsubstituted C₆-C₂₀ aryl group. In an example where the linker Lis a direct bond, the head portion H and the tail portion T can have a directly bonded form.

The adhesion reinforcement material ARM can include an amphoteric material. For example, the adhesion reinforcement material ARM can include a hydrophilic group and a hydrophobic group. Referring to FIG. 12, in one or more aspects, one of the head portion H and the tail portion T can be a hydrophilic group, and the other of the head portion H and the tail portion T can be a hydrophobic group. For example, the head portion H can be a hydrophobic group, and the tail portion T can be a hydrophilic group. In another example, the head H can be a hydrophilic group and the tail T can be a hydrophobic group.

Hereinafter, for convenience of description, discussions are provided based on examples where the head H is a hydrophobic group and the tail Tis a hydrophilic group.

The hydrophobic group can include a substituted or unsubstituted C₁-C₂₀ fluorinated alkyl group. For example, the hydrophobic group can include at least three fluorine atoms. The hydrophobic group can be a perfluorinated alkyl group including —CF₃ or —CF₂CF₃ at the terminal group. As the adhesion reinforcement material ARM includes the hydrophobic group, the adhesion reinforcement material ARM can effectively induce chain entanglement with a cathode patterning material included in the metal patterning layer MPL, and thereby, the adhesion between the adhesion reinforcing layer and the metal patterning layer MPL can be improved.

The hydrophilic group can include at least one selected from a group consisting of a hydroxyl group (—OH), a carboxyl group (—COOH), an ester group (—C(═O)O—), a carbonyl group (—C(═O)—), an ether group (—O—), a sulfide group (—S—), an amine group (—NR′R″), an amide group (—C(═O)NR′R″), and one or more combinations thereof. For example, R′ and R″ can be independent from each other, and each of R′ and R″ can be selected from hydrogen, a substituted or unsubstituted C₁ to C₂₀ alkyl group, or a substituted or unsubstituted C₁ to C₂₀ alkoxy group. As the adhesion reinforcement material ARM includes the hydrophilic group, the adhesion reinforcement material ARM can induce chain interaction with an organic material included in the intermediate layer EL or the capping layer, and thereby, the adhesion between the adhesion reinforcing layer and the intermediate layer EL and/or the capping layer can be improved.

It should be noted here that the term “substitution”, “substituted”, or a term equivalent to these can mean that a substituent other than hydrogen (H) is bonded to a corresponding carbon. In one or more aspects, one or more substituents used herein can be deuterium, halogen, an alkyl group, a heteroalkyl group, an alkoxy group, an aryloxy group, an alkynyl group, an aryl group, a heteroaryl group, a carbonyl group, a carboxylic acid group, a nitrile group, a cyano group, an amino group, and/or one or more combinations thereof.

For example, the adhesion reinforcement material ARM can be a compound as follows, but aspects of the present disclosure are not limited thereto.

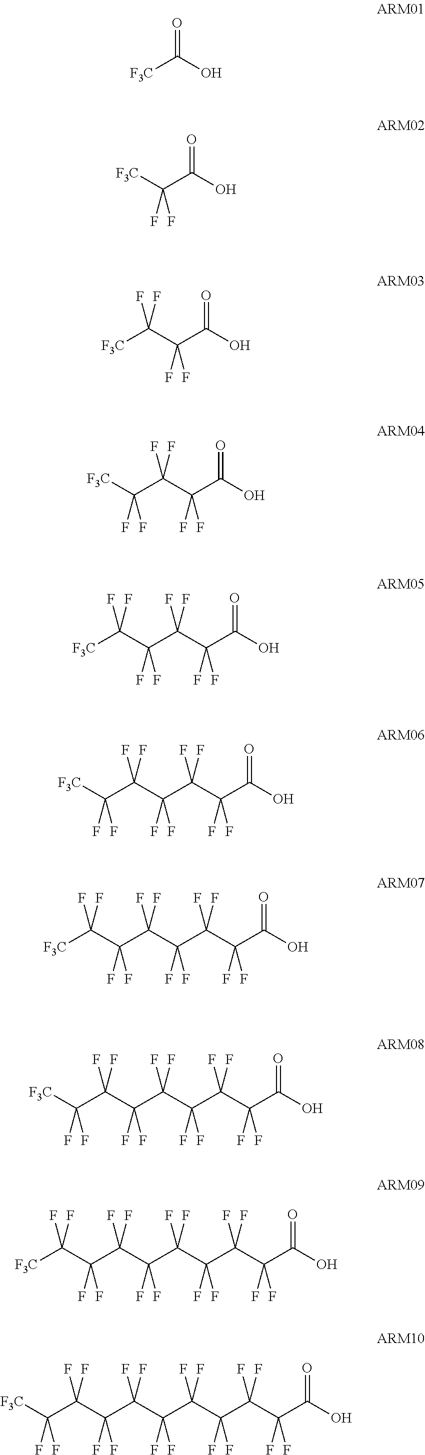

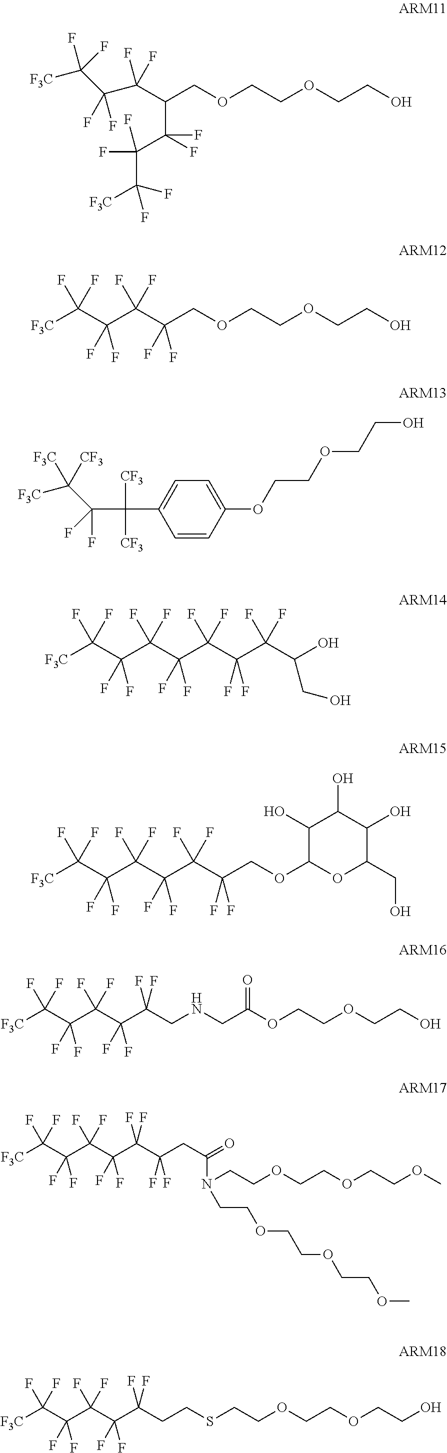

Therefore, since the adhesion reinforcement material ARM includes an amphoteric material including a hydrophilic group and a hydrophobic group, the display device 100 can provide an advantage of improving the adhesion between the intermediate layer EL and the metal patterning layer MPL and/or the metal patterning layer MPL and the capping layer CPL based on the structure where the adhesion reinforcing layer including the adhesion reinforcement material ARM is disposed on at least one surface of the metal patterning layer MPL.

FIGS. 13 to 15 illustrate various example enlarged cross-sections of area A illustrated in FIG. 11 according to aspects of the present disclosure. In discussions that follow for the configuration of FIGS. 13 to 15, discussions for features and configurations equal, substantially equal, or similar to the features and configurations described with reference to FIGS. 1 to 12 are omitted or briefly described for conciseness.

Referring to FIG. 13, in one or more example embodiments of the present disclosure, the display panel 110 can include the second planarization layer PLN2, the bank BK disposed on the second planarization layer PLN2, the intermediate layer EL disposed on the bank BK, the cathode electrode CE disposed on the intermediate layer EL, the capping layer CPL disposed on the cathode electrode CE, and the encapsulation layer ENCAP including a first encapsulation layer PAS1 and a second encapsulation layer PCL, which are disposed on the capping layer CPL. The cathode electrode CE can include a cathode hole CH. The cathode hole CH formed in the cathode electrode CE can be disposed to overlap with at least a portion of the transmissive area TA of the optical area OA.

The intermediate layer EL can include an emission layer EML, a first common intermediate layer COM1 between an anode electrode AE and the emission layer EML, and a second common intermediate layer COM2 between the emission layer EML and the cathode electrode CE. A layer including the first common intermediate layer COM1 and the second common intermediate layer COM2 can be referred to as a common intermediate layer EL_COM. The emission layer EML can be disposed in the bank hole and not disposed in the cathode hole CH.

For example, the emission layer EML can be disposed for each light emitting area, and the common intermediate layer EL_COM can be disposed commonly across all or some of a plurality of light emitting areas and a non-light emitting area. For example, the emission layer EML and the common intermediate layer EL_COM can be disposed commonly across all or some of a plurality of light emitting areas and a non-light emitting area.

The first common intermediate layer COM1 can include a hole injection layer HIL and a hole transport layer HTL, and the like. The second common intermediate layer COM2 can include an electron transport layer ETL, an electron injection layer EIL, and the like.

The electron injection layer EIL can be disposed on the electron transport layer ETL, and the electron injection layer EIL may not be disposed in the cathode hole CH. For example, a portion of the upper surface of the electron transport layer ETL can be exposed in the cathode hole CH.

An adhesion reinforcing layer ARL can be disposed in the cathode hole CH. The adhesion reinforcing layer ARL can include an adhesion reinforcement material ARM. A metal patterning layer MPL can be disposed on the adhesion reinforcing layer ARL. The metal patterning layer MPL can include a cathode patterning material. For example, the adhesion reinforcing layer ARL and the metal patterning layer MPL can be stacked on an upper surface of the electron transport layer ETL in the cathode hole CH.

The adhesion reinforcement material ARM can include an amphoteric material including a hydrophilic group and a hydrophobic group. For example, the hydrophilic group of the adhesion reinforcement material ARM included in the adhesion reinforcing layer ARL can contact the intermediate layer EL, and the hydrophobic group of the adhesion reinforcement material ARM included in the adhesion reinforcing layer ARL can contact the metal patterning layer MPL. For example, the hydrophilic group of the adhesion reinforcement material ARM included in the adhesion reinforcing layer ARL can contact the second common intermediate layer COM2 among the layers of the intermediate layer EL. For example, the hydrophilic group of the adhesion reinforcement material ARM included in the adhesion reinforcing layer ARL can contact the electron transport layer ETL among the layers of the second common intermediate layer COM2.

Therefore, chain entanglement can be effectively induced between the adhesion reinforcing layer ARL and the metal patterning layer MPL, and thereby, the adhesion between the adhesion reinforcing layer ARL and the metal patterning layer MPL can be improved. Further, chain interaction can be induced between the adhesion reinforcing layer ARL and the intermediate layer EL including the electron transport layer ETL, and thereby, the adhesion between the adhesion reinforcing layer ARL and the intermediate layer EL can be improved.

In one or more aspects, the adhesion reinforcing layer ARL can further include an electron transport material in addition to the adhesion reinforcement material ARM. The electron transport material can be the same material as a material included in the electron transport layer ETL, or can be a different material from the material included in the electron transport layer ETL.

The electron transport material included in the adhesion reinforcing layer ARL can contact the intermediate layer EL and the metal patterning layer MPL together or concurrently. The intermediate layer EL can be the second common intermediate layer COM2 or the electron transport layer ETL. The electron transport material included in the adhesion reinforcing layer ARL can act as a bridge between the intermediate layer EL and the metal patterning layer MPL. For example, the electron transport material included in the adhesion reinforcing layer ARL can increase an area where the hydrophilic group included in the adhesion reinforcement material ARM contacts the intermediate layer EL and the electron transport material, and thereby further improve chain interaction between the adhesion reinforcing layer ARL and the intermediate layer EL.

the capping layer CPL can be disposed on the cathode electrode CE. For example, the capping layer CPL can be disposed on the cathode electrode CE such that the capping layer CPL covers the metal patterning layer MPL disposed in the cathode hole CH. The capping layer CPL can be in the form of a single layer or a multilayer. The capping layer CPL can be an organic capping layer and/or an inorganic capping layer.

The display device 100 can provide an advantage of improving the adhesion between the intermediate layer EL and the metal patterning layer MPL based on the structure where the adhesion reinforcing layer ARL is disposed between the intermediate layer EL and the metal patterning layer MPL.

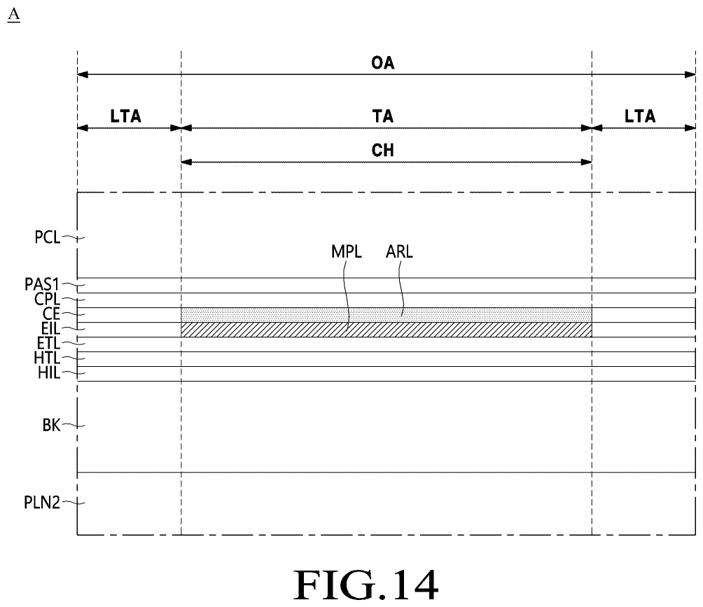

FIG. 14 is another example enlarged view of area A of FIG. 11. In discussions that follow for the configuration of FIG. 14, discussions for features and configurations equal, substantially equal, or similar to the features and configurations described with reference to FIGS. 1 to 13 are omitted or briefly described for conciseness.

The cross-sectional structure of FIG. 14 can be similar to the cross-sectional structure of FIG. 13 such that the remaining stack-up configurations of FIGS. 13 and 14 are substantially the same except that the stack-up configuration of an adhesion reinforcing layer ARL and a metal patterning layer MPL in FIG. 13 is changed. Considering such a similarity, discussions for the cross-sectional structure of FIG. 14 are provided by focusing on the different configuration from that of FIG. 13.

Referring to FIG. 14, in one or more example embodiments of the present disclosure, a metal patterning layer MPL can be disposed in a cathode hole CH. The metal patterning layer MPL can include a cathode patterning material. An adhesion reinforcing layer ARL can be disposed on the metal patterning layer MPL. The adhesion reinforcing layer ARL can include an adhesion reinforcement material ARM. For example, the metal patterning layer MPL and the adhesion reinforcing layer ARL can be stacked on the upper surface of the electron transport layer ETL in the cathode hole CH. The cathode hole CH formed in the cathode electrode CE can be disposed to overlap with at least a portion of the transmissive area TA of the optical area OA.

The capping layer CPL can be disposed on the cathode electrode CE in the display area. For example, the capping layer CPL can be disposed on the cathode electrode CE such that the capping layer CPL covers the adhesion reinforcing layer ARL disposed in the cathode hole CH. The capping layer CPL can be in the form of a single layer or a multilayer. The capping layer CPL can be an organic capping layer and/or an inorganic capping layer. A portion or layer of the capping layer CPL directly contacting the adhesion reinforcing layer ARL can be the organic capping layer.

The adhesion reinforcement material ARM can include an amphoteric material including a hydrophilic group and a hydrophobic group. For example, the hydrophilic group of the adhesion reinforcement material ARM included in the adhesion reinforcing layer ARL can contact the capping layer CPL, and the hydrophobic group of the adhesion reinforcement material ARM included in the adhesion reinforcing layer ARL can contact the metal patterning layer MPL. For example, the hydrophilic group of the adhesion reinforcement material ARM included in the adhesion reinforcing layer ARL can contact the organic capping layer among the layers of the capping layers CPL.

Therefore, chain entanglement can be effectively induced between the adhesion reinforcing layer ARL and the metal patterning layer MPL, and thereby, the adhesion between the adhesion reinforcing layer ARL and the metal patterning layer MPL can be improved. Further, chain interaction can be induced between the adhesion reinforcing layer ARL and the capping layer CPL, and thereby, the adhesion between the adhesion reinforcing layer ARL and the capping layer CPL can be improved.

According to the configurations discussed above, the display device 100 can provide an advantage of improving the adhesion between the metal patterning layer MPL and the capping layer CPL based on the structure where the adhesion reinforcing layer ARL is disposed between the metal patterning layer MPL and the capping layer CPL.

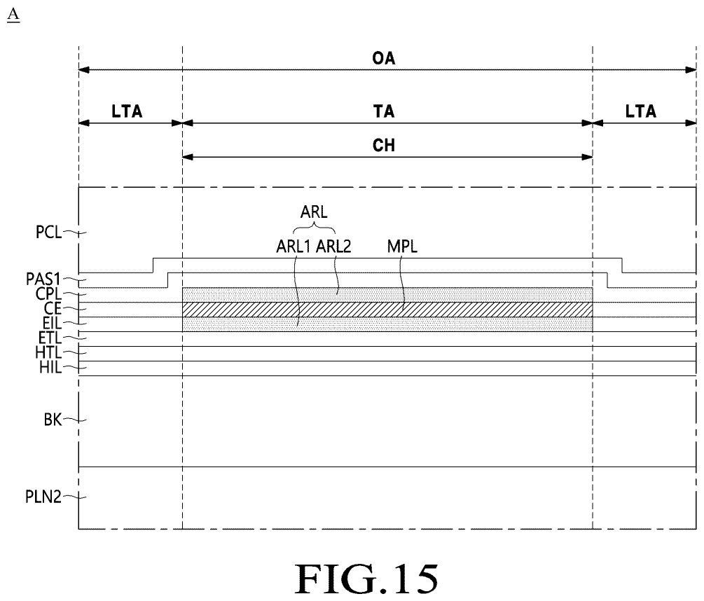

FIG. 15 is another example enlarged view of area A of FIG. 11. In discussions that follow for the configuration of FIG. 15, discussions for features and configurations equal, substantially equal, or similar to the features and configurations described with reference to FIGS. 1 to 14 are omitted or briefly described for conciseness.

The cross-sectional structure of FIG. 15 can be similar to the cross-sectional structure of FIG. 13 such that the remaining stack-up configurations of FIGS. 13 and 15 are substantially the same except that the stack-up configuration of an adhesion reinforcing layer ARL and a metal patterning layer MPL in FIG. 13 is changed. Considering such a similarity, discussions for the cross-sectional structure of FIG. 15 are provided by focusing on the different configuration from that of FIG. 13.

Referring to FIG. 15, in one or more example embodiments of the present disclosure, a first adhesion reinforcing layer ARL1 can be disposed in a cathode hole CH. The first adhesion reinforcing layer ARL1 can include a first adhesion reinforcement material. A metal patterning layer MPL can be disposed on the first adhesion reinforcing layer ARL1. The metal patterning layer MPL can include a cathode patterning material. A second adhesion reinforcing layer ARL2 can be disposed on the metal patterning layer MPL. The second adhesion reinforcing layer ARL2 can include a second adhesion reinforcement material. For example, the first adhesion reinforcing layer ARL1, the metal patterning layer MPL, and the second adhesion reinforcing layer ARL2 can be stacked on the upper surface of the electron transport layer ETL in the cathode hole CH. The cathode hole CH formed in the cathode electrode CE can be disposed to overlap with at least a portion of the transmissive area TA of the optical area OA.

The capping layer CPL can be disposed on the cathode electrode CE in the display area and cover the cathode hole CH. For example, the capping layer CPL can be disposed on the cathode electrode CE such that the capping layer CPL covers the second adhesion reinforcing layer ARL2 disposed in the cathode hole CH. The capping layer CPL can be in the form of a single layer or a multilayer. The capping layer CPL can be an organic capping layer and/or an inorganic capping layer. A portion or layer of the capping layer CPL directly contacting the second adhesion reinforcing layer ARL2 can be the organic capping layer.

The first adhesion reinforcement material can include a first amphoteric material including a hydrophilic group and a hydrophobic group. For example, the hydrophilic group of the first adhesion reinforcement material included in the first adhesion reinforcing layer ARL1 can contact the intermediate layer EL, and the hydrophobic group of the first adhesion reinforcement material included in the first adhesion reinforcing layer ARL can contact the metal patterning layer MPL. For example, the hydrophilic group of the first adhesion reinforcement material included in the first adhesion reinforcing layer ARL1 can contact the second common intermediate layer COM2 among the layers of the intermediate layers EL. For example, the hydrophilic group of the first adhesion reinforcement material included in the first adhesion reinforcing layer ARL1 can contact the electron transport layer ETL among the layers of the second common intermediate layer COM2. The second adhesion reinforcement material can include a second amphoteric material including a hydrophilic group and a hydrophobic group. For example, the hydrophilic group of the second adhesion reinforcement material included in the second adhesion reinforcing layer ARL2 can contact the capping layer CPL, and the hydrophobic group of the second adhesion reinforcement material included in the second adhesion reinforcing layer ARL can contact the metal patterning layer MPL. For example, the hydrophilic group of the second adhesion reinforcement material included in the second adhesion reinforcing layer ARL2 can contact the organic capping layer among the layers of the capping layer CPL. In one or more aspects of the present disclosure, the first amphoteric material included in the first adhesion reinforcement material and the second amphoteric material included in the second adhesion reinforcement material can be the same or different materials.

Therefore, chain interaction can be induced between the first adhesion reinforcing layer ARL1 and the intermediate layer EL including the electron transport layer ETL, and thereby, the adhesion between the first adhesion reinforcing layer ARL and the intermediate layer EL can be improved. Further, chain entanglement can be effectively induced between the first adhesion reinforcing layer ARL1 and the metal patterning layer MPL, and thereby, the adhesion between the first adhesion reinforcing layer ARL and the metal patterning layer MPL can be improved.

Further, chain entanglement can be effectively induced between the second adhesion reinforcing layer ARL2 and the metal patterning layer MPL, and thereby, the adhesion between the second adhesion reinforcing layer ARL2 and the metal patterning layer MPL can be improved. Further, chain interaction can be induced between the second adhesion reinforcing layer ARL2 and the capping layer CPL, and thereby, the adhesion between the second adhesion reinforcing layer ARL and the capping layer CPL can be improved.

In one or more aspects of the present disclosure, the first adhesion reinforcing layer ARL1 can further include an electron transport material in addition to the first adhesion reinforcement material. The electron transport material can be the same material as a material included in the electron transport layer ETL, or can be a different material from the material included in the electron transport layer ETL.

The electron transport material included in the first adhesion reinforcing layer ARL1 can contact the intermediate layer EL and the metal patterning layer MPL together or concurrently. The intermediate layer EL can be the second common intermediate layer COM2 or the electron transport layer ETL. The electron transport material included in the first adhesion reinforcing layer ARL1 can act as a bridge between the intermediate layer EL and the metal patterning layer MPL. For example, the electron transport material included in the first adhesion reinforcing layer ARL1 can increase an area in which the hydrophilic group included in the first adhesion reinforcement material contacts the intermediate layer EL and the electron transport material, and thereby further improve the chain interaction between the first adhesion reinforcing layer ARL1 and the intermediate layer EL.

According to the configurations discussed above, the display device 100 can provide an advantage of increasing the adhesion between the intermediate layer EL and the metal patterning layer MPL and the adhesion between the metal patterning layer MPL and the capping layer CPL based on the structure where the adhesion reinforcing layer ARL is disposed between the intermediate layer EL and the metal patterning layer MPL and between the metal patterning layer MPL and the capping layer CPL.

Hereinafter, discussions are provided based on one or more example embodiments of the present disclosure and one or more comparative examples, but aspects of the present disclosure are not limited to the technical idea described in the following example embodiment(s) and comparative example(s).

### Comparative Examples

In a comparative example, a display panel have been prepared that includes a metal patterning layer is stacked on an intermediate layer including an electron transport layer. The display panel according to the comparative example can be a display panel manufactured without including an adhesion reinforcing layer between the intermediate layer and a metal patterning layer.

### Example Embodiments

In an example embodiment of the present disclosure, a display panel has been prepared in the same manner as the comparative example except that an adhesion reinforcing layer including a compound ARM07 (perfluoro octanoic acid) is stacked between an electron transport layer and a metal patterning layer.

### [Characteristic Evaluation]

The peeling of the metal patterning layer has been evaluated using Instron equipment.

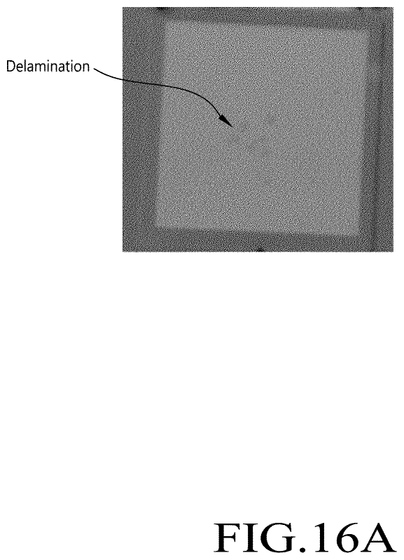

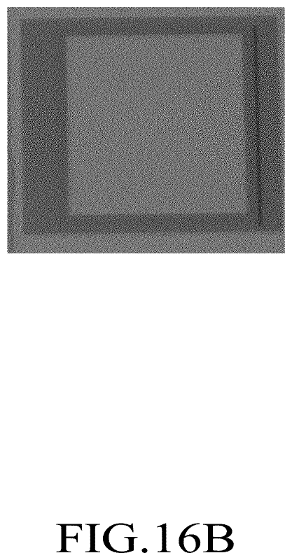

FIG. 16A is a photograph showing an image according to the comparative example not including an adhesion reinforcing layer. In contrast, FIG. 16B is a photograph showing an image according to the example embodiment of the present disclosure including an adhesion reinforcing layer.

Referring to FIG. 16A, it can be confirmed that a peeling phenomenon (delamination) occurs in a portion of the transmissive area in the comparative example. However, referring to FIG. 16B, it can be confirmed that no peeling phenomenon occurs at all in the transmissive area in the example embodiment of the present disclosure, which is advantageous.

The examples, aspects, and embodiments of the present disclosure described above will be briefly described as follows.

According to the one or more example embodiments of the present disclosure described herein, a display device can include a substrate including a display area in which an image is displayed, the display area including a transmissive area in which light is transmitted and a normal area located outside of the transmissive area, an anode electrode located on the substrate, a bank located on the anode electrode and including a bank hole for exposing a portion of the anode electrode, an intermediate layer disposed in the display area and contacting an upper surface of the portion of the anode electrode exposed through the bank hole, a cathode electrode disposed in the display area, located on the intermediate layer, and including a cathode hole overlapping with at least a portion of the transmissive area, a first adhesion reinforcing layer disposed in the cathode hole and including a first amphoteric material, and a metal patterning layer disposed on the first adhesion reinforcing layer and including a cathode patterning material.

In one or more aspects of the present disclosure, the first amphoteric material can include a hydrophilic group and a hydrophobic group. In one or more aspects of the present disclosure, the hydrophilic group can contact the intermediate layer, and the hydrophobic group can contact the metal patterning layer.

In one or more aspects of the present disclosure, the hydrophobic group can include a substituted or unsubstituted C₁-C₂₀ fluorinated alkyl group.

In one or more aspects of the present disclosure, the hydrophilic group can include at least one selected from a group consisting of a hydroxyl group (—OH), a carboxyl group (—COOH), an ester group (—C(═O)O—), a carbonyl group (—C(═O)—), an ether group (—O—), a sulfide group (—S—), an amine group (—NR′R″, where each of R′ and R″ being independent from each other is hydrogen, a substituted or unsubstituted C₁ to C₂₀ alkyl group, or a substituted or unsubstituted C₁ to C₂₀ alkoxy group), an amide group (—C(—O)NR′R″, wherein each of R′ and R″ being independent from each other is hydrogen, a substituted or unsubstituted C₁ to C₂₀ alkyl group, or a substituted or unsubstituted C₁ to C₂₀ alkoxy group), and one or more combinations thereof.

In one or more aspects of the present disclosure, the cathode patterning material can be an organic compound comprising a halogen element.

In one or more aspects of the present disclosure, the intermediate layer can include an emission layer.

In one or more aspects of the present disclosure, the emission layer can be disposed in the bank hole and may not be disposed in the cathode hole.

In one or more aspects of the present disclosure, the intermediate layer can include an electron transport layer and an electron injection layer disposed on the electron transport layer, and the electron injection layer may not be disposed in the cathode hole.

In one or more aspects of the present disclosure, the hydrophilic group can contact the electron transport layer.

In one or more aspects of the present disclosure, the first adhesion reinforcing layer can further include an electron transport material, and the electron transport material can contact the electron transport layer and the metal patterning layer.

In one or more aspects of the present disclosure, the electron transport material can be the same material as a material included in the electron transport layer.

In one or more aspects of the present disclosure, the display device can further include a capping layer disposed in the display area, located on the cathode electrode, and covering the cathode hole.

In one or more aspects of the present disclosure, the display device can further include a second adhesion reinforcing layer disposed between the metal patterning layer and the capping layer and comprising a second amphoteric material.

In one or more aspects of the present disclosure, the second amphoteric material can include a hydrophilic group and a hydrophobic group. In one or more aspects of the present disclosure, the hydrophilic group can contact the capping layer, and the hydrophobic group can contact the metal patterning layer.

In one or more aspects of the present disclosure, the first amphoteric material and the second amphoteric material can be a same material.

In one or more aspects of the present disclosure, the display device can further include an optical electronic device located under the substrate and overlapped with at least a portion of the transmissive area.

According to the one or more example embodiments of the present disclosure described herein, a display device can include a substrate including a display area in which an image is displayed, the display area including an optical area in which light is transmitted and a normal area located outside of the optical area, an anode electrode located on the substrate, a bank located on the anode electrode and including a bank hole for exposing a portion of the anode electrode, an intermediate layer disposed in the display area and contacting an upper surface of the portion of the anode electrode exposed through the bank hole, a cathode electrode disposed in the display area, located on the intermediate layer, and including a cathode hole overlapping with at least a portion of the transmissive area, a metal patterning layer disposed in the cathode hole and including a cathode patterning material, an adhesion reinforcing layer disposed on the metal patterning layer and including an amphoteric material, and a capping layer disposed in the display area, located on the cathode electrode, and covering the cathode hole.

In one or more aspects of the present disclosure, the first amphoteric material can include a hydrophilic group and a hydrophobic group. In one or more aspects of the present disclosure, the hydrophilic group can contact the intermediate layer, and the hydrophobic group can contact the metal patterning layer.

In one or more aspects of the present disclosure, the hydrophobic group can include a substituted or unsubstituted C₁-C₂₀ fluorinated alkyl group.

In one or more aspects of the present disclosure, the hydrophilic group can include at least one selected from a group consisting of a hydroxyl group (—OH), a carboxyl group (—COOH), an ester group (—C(═O)O—), a carbonyl group (—C(═O)—), an ether group (—O—), a sulfide group (—S—), an amine group (—NR′R″, where each of R′ and R″ being independent from each other is hydrogen, a substituted or unsubstituted C₁ to C₂₀ alkyl group, or a substituted or unsubstituted C₁ to C₂₀ alkoxy group), an amide group (—C(—O)NR′R″, wherein each of R′ and R″ being independent from each other is hydrogen, a substituted or unsubstituted C₁ to C₂₀ alkyl group, or a substituted or unsubstituted C₁ to C₂₀ alkoxy group), and one or more combinations thereof.

In one or more aspects of the present disclosure, the cathode patterning material can be an organic compound comprising a halogen element.

In one or more aspects of the present disclosure, the intermediate layer can include an electron transport layer and an electron injection layer disposed on the electron transport layer, and the electron injection layer may not be disposed in the cathode hole.

In one or more aspects of the present disclosure, the display device can further include an optical electronic device located under the substrate and overlapped with at least a portion of the transmissive area.

The above description has been presented to enable any person skilled in the art to make, use and practice the technical features of the present disclosure, and has been provided in the context of a particular application and its requirements as examples. Various modifications, additions and substitutions to the described embodiments of the present disclosure will be readily apparent to those skilled in the art, and the principles described herein can be applied to other embodiments and applications without departing from the scope of the present disclosure. The above description and the accompanying drawings provide an example of the technical idea of the present disclosure for illustrative purposes only. For example, the disclosed embodiments are intended to illustrate the scope of the technical features of the present disclosure.

What is claimed is:

1. A display device comprising:
a substrate comprising a display area in which an image is displayed, the display area comprising a transmissive area in which light is transmitted and a normal area located outside of the transmissive area;
an anode electrode located on the substrate;
a bank located on the anode electrode and comprising a bank hole for exposing a portion of the anode electrode;
an intermediate layer disposed in the display area and contacting an upper surface of the portion of the anode electrode exposed through the bank hole;
a cathode electrode disposed in the display area, located on the intermediate layer, and comprising a cathode hole overlapping with at least a portion of the transmissive area;
a first adhesion reinforcing layer disposed in the cathode hole and comprising a first amphoteric material; and
a metal patterning layer disposed on the first adhesion reinforcing layer and comprising a cathode patterning material.

2. The display device of claim 1, wherein the first amphoteric material comprises a hydrophilic group and a hydrophobic group, and
wherein the hydrophilic group contacts the intermediate layer, and the hydrophobic group contacts the metal patterning layer.

3. The display device of claim 2, wherein the hydrophobic group comprises a substituted or unsubstituted C₁-C₂₀ fluorinated alkyl group.

4. The display device of claim 2, wherein the hydrophilic group comprises at least one selected from a group consisting of a hydroxyl group (—OH), a carboxyl group (—COOH), an ester group (—C(═O)O—), a carbonyl group (—C(═O)—), an ether group (—O—), a sulfide group (—S—), an amine group (—NR′R″, where each of R′ and R″ being independent from each other is hydrogen, a substituted or unsubstituted C₁ to C₂₀ alkyl group, or a substituted or unsubstituted C₁ to C₂₀ alkoxy group), an amide group (—C(—O)NR′R″, wherein each of R′ and R″ being independent from each other is hydrogen, a substituted or unsubstituted C₁ to C₂₀ alkyl group, or a substituted or unsubstituted C₁ to C₂₀ alkoxy group), and one or more combinations thereof.

5. The display device of claim 2, wherein the cathode patterning material is an organic compound comprising a halogen element.

6. The display device of claim 2, wherein the intermediate layer comprises an emission layer, and the emission layer is disposed in the bank hole and is not disposed in the cathode hole.

7. The display device of claim 2, wherein the intermediate layer comprises an electron transport layer and an electron injection layer disposed on the electron transport layer, and the electron injection layer is not disposed in the cathode hole.

8. The display device of claim 7, wherein the hydrophilic group contacts the electron transport layer.

9. The display device of claim 7, wherein the first adhesion reinforcing layer further comprises an electron transport material, and the electron transport material contacts the electron transport layer and the metal patterning layer.

10. The display device of claim 9, wherein the electron transport material is the same material as a material included in the electron transport layer.

11. The display device of claim 1, further comprising:
a capping layer disposed in the display area, located on the cathode electrode, and covering the cathode hole; and
a second adhesion reinforcing layer disposed between the metal patterning layer and the capping layer and comprising a second amphoteric material.

12. The display device of claim 11, wherein the second amphoteric material comprises a hydrophilic group and a hydrophobic group, and
wherein the hydrophilic group contacts the capping layer, and the hydrophobic group contacts the metal patterning layer.

13. The display device of claim 12, wherein the first amphoteric material and the second amphoteric material are a same material.

14. The display device of claim 1, further comprising an optical electronic device located under the substrate and overlapped with at least a portion of the transmissive area.

15. A display device comprising:
a substrate comprising a display area in which an image is displayed, the display area comprising a transmissive area in which light is transmitted and a normal area located outside of the transmissive area;
an anode electrode located on the substrate;
a bank located on the anode electrode and comprising a bank hole for exposing a portion of the anode electrode;
an intermediate layer disposed in the display area and contacting an upper surface of the portion of the anode electrode exposed through the bank hole;
a cathode electrode disposed in the display area, located on the intermediate layer, and comprising a cathode hole overlapping with at least a portion of the transmissive area;
a metal patterning layer disposed in the cathode hole and comprising a cathode patterning material;
an adhesive reinforcing layer disposed on the metal patterning layer and comprising an amphoteric material; and
a capping layer disposed in the display area, located on the cathode electrode, and covering the cathode hole.

16. The display device of claim 15, wherein the amphoteric material comprises a hydrophilic group and a hydrophobic group, and
wherein the hydrophilic group contacts the capping layer, and the hydrophobic group contacts the metal patterning layer.

17. The display device of claim 16, wherein the hydrophobic group comprises a substituted or unsubstituted C₁-C₂₀ fluorinated alkyl group.

18. The display device of claim 16, wherein the hydrophilic group comprises at least one selected from a group consisting of a hydroxyl group (—OH), a carboxyl group (—COOH), an ester group (—C(═O)O—), a carbonyl group (—C(═O)—), an ether group (—O—), a sulfide group (—S—), an amine group (—NR′R″, where each of R′ and R″ being independent from each other is hydrogen, a substituted or unsubstituted C₁ to C₂₀ alkyl group, or a substituted or unsubstituted C₁ to C₂₀ alkoxy group), an amide group (—C(═O)NR′R″, wherein each of R′ and R″ being independent from each other is hydrogen, a substituted or unsubstituted C₁ to C₂₀ alkyl group, or a substituted or unsubstituted C₁ to C₂₀ alkoxy group), and one or more combinations thereof.

19. The display device of claim 16, wherein the cathode patterning material is an organic compound comprising a halogen element.

20. The display device of claim 16, wherein the intermediate layer comprises an electron transport layer and an electron injection layer disposed on the electron transport layer, and the electron injection layer is not disposed in the cathode hole.
